(19) United States
(12) Patent Application Publication
(10) Pub. No.: US 2011/0063592 A1
(43) Pub. Date: Mar. 17, 2011

(54) FLUORESCENT FILM, METHOD OF FORMING FLUORESCENT FILM, MULTILAYER DIELECTRIC FILM, OPTICAL ELEMENT, OPTICAL SYSTEM, IMAGING UNIT, OPTICAL PROPERTY MEASURING APPARATUS, METHOD OF MEASURING OPTICAL PROPERTY, EXPOSURE APPARATUS, EXPOSURE METHOD, AND METHOD OF MANUFACTURING DEVICE

(75) Inventors: Yoshinobu EZURA, Yokohama-shi (JP); Hitoshi ISHIZAWA, Kawasaki-shi (JP)

(73) Assignee: NIKON CORPORATION, Tokyo (JP)

(21) Appl. No.: 12/879,404

(22) Filed: Sep. 10, 2010

Related U.S. Application Data
(63) Continuation of application No. PCT/JP2009/054552, filed on Mar. 10, 2009.

(30) Foreign Application Priority Data
Mar. 10, 2008 (JP) P2008-059700
Jul. 28, 2008 (JP) P2008-193560

(51) Int. Cl. G03B 27/42; C09K 11/85; G03F 7/20; G01J 1/58

(52) U.S. Cl. 355/53; 252/301.4 H; 430/325; 250/458.1

(57) ABSTRACT

A fluorescent film including a base material constituted of a UV-permeable fluoride, and an activator doped in the base material, wherein the activator contains a transition element or a rare earth element and emits fluorescent light in the base material when ultraviolet light is irradiated to the base material. Also disclosed are a multilayer dielectric film including the fluorescent film, and an optical element, an imaging unit, an optical property measuring apparatus, an exposure apparatus, an exposure method, and a device manufacturing method utilizing the fluorescent film.

### CROSS-REFERENCE TO RELATED APPLICATION

This is a Continuation Application of International Application No. PCT/JP2009/054552 filed on Mar. 10, 2009, and published as WO 2009/113544, which claims priority to Japanese Patent Application No. 2008-59700 filed on Mar. 10, 2008 and Japanese Patent Application No. 2008-193560 filed on Jul. 28, 2008. The contents of the aforementioned applications are incorporated herein by reference.

### BACKGROUND

The present invention relates to a fluorescent film that is activated by ultraviolet light and emits fluorescent light, and to a method of forming the fluorescent film. The present invention also relates to a multilayer dielectric film, an optical element, an optical system, an imaging unit, an optical property measuring apparatus, a method of measuring optical property, an exposure apparatus, an exposure method, and a device manufacturing method utilizing the fluorescent film.

An exposure apparatus such as a stepper has been used as an apparatus of manufacturing microdevices, for example, semiconductor devices or liquid-crystal display devices. A projection optical system of this type of exposure apparatus requires high resolution. To achieve the high resolution of the projection optical system, the optical properties of the projection optical system (for example, imaging properties such as distortion, field curvature and the like, and wavefront aberration and the like) are measured to a high accuracy, and an error between the designed optical properties and the actual optical properties must be corrected. In this context, an optical property measurement apparatus has been proposed, for example, in US2005/0122506A1. In the apparatus described in US2005/0122506A1, periodic patterns (repeated light-dark pattern) are arranged on an object plane and image plane of the projection optical system, and distortion is measured using a moire fringe formed by the two periodic patterns.

However, a large sized relay lens is required to measure distortion across a large region in a single measurement by the above-described measurement apparatus. Increased size of the relay lens may cause difficulty in mounting the measurement apparatus in an exposure apparatus. Therefore, the use of an optical element provided with a light guide member configured as a bundle of a plurality of optical fibers (fiber optical plate: hereafter referred to as “FOP”) is under investigation as an alternative to the relay lens of an optical property measurement apparatus.

A fluorescent material has been used as a material to convert ultraviolet light to visible light. There is a long history of the development of fluorescent materials. For example, as an representative application, fluorescent materials are used in fluorescent lamp. Recently, fluorescent materials have become indispensable materials in various illumination techniques using light emitting diodes (LED).

Fluorescent materials which have been used in fluorescent lamps (low-pressure mercury vapor lamps) include oxide-based materials, where a halophosphate, phosphate, silicate, or the like are used as a base material. These fluorescent materials are excited by light of 254 nm in wavelength emitted from an excited mercury vapor and emit various types of fluorescence. In recent years, a plasma display panel (PDP) has been developed. The plasma display panel displays an image by applying a high electric voltage to an encapsulated rare gas such as xenon (Xe), neon (Ne), or the like to thereby emit fluorescence by vacuum ultraviolet light having a wavelength of 147 nm or 173 nm generated during electrical discharge into the gas. The fluorescent material used in a PDP also includes oxide-based materials such as aluminates, silicates, borates, or the like.

These fluorescent materials are generally manufactured utilizing solid phase-, liquid phase-, or gas phase reactions, and are in a powder state (particle diameter of several micrometers). Formation of a thin fluorescent layer is often performed by applying a fluorescent material to a substrate using a printing technique. A high-viscosity solution is mixed with the fluorescent powder, and is applied to a substrate using a printing technique such as screen printing. Then the solvent in the coated layer is evaporated using a high-temperature sintering process to fuse the binder agent and thereby fixing the fluorescent powder to the substrate and form the fluorescent layer.

In a laser optical system utilizing ultraviolet laser light, a fluorescent material is used in a beam profiler confirming a laser beam profile, or a beam checker or the like to confirm a laser beam path. As described-above, these types of fluorescent materials are generally made of a fluorescent powder fixed to a substrate. On the other hand, recently developed fluorescent materials include transparent materials such as glass that emits fluorescence (for example, Japanese Patent No. 3961585, or Japanese Unexamined Patent Application, First Publication No. 2006-265012). In these types of fluorescence-emitting glass, a rare-earth or transition metal ions are impregnated in a fluorophosphate-based oxide-based glass to configure a fluorescent materials while maintaining transparent properties. This type of fluorescent glass has an object of converting ultraviolet light to visible light that can be observed visually, and is used, for example, in adjustment of an optical axis of laser light such as an excimer laser.

### SUMMARY

It is preferable to use short wavelength light to perform measurement of optical properties with high accuracy. Preferably, properties of an optical system that utilizes ultraviolet light, for example, an exposure apparatus utilizing an excimer laser as a light source, is measured using the ultraviolet light of a wavelength actually used in the optical system. A light guide member such as an FOP may be used in an apparatus of measuring ultraviolet light. However, it is known that the FOP absorbs ultraviolet light. Therefore, where an FOP is used in the above-described optical property measurement apparatus, deterioration of the FOP is likely to occur because of irradiation of strong short-wavelength ultraviolet light from the light source onto the FOP. Therefore, there has been requirements for improving FOP to reduce deterioration due to UV irradiation.

On the other hand, where a powdered fluorescent material fixed to a substrate is used in converting ultraviolet light to visible light, reduction of thickness of the fluorescent layer is limited due to the constraint of manufacturing process. In addition, the fluorescent layer has a porous configuration packed with particles of several micrometers, and includes many pores. Since these pores and wavelength of the light have similar dimensions, the ultraviolet light or fluorescent light is scattered by the pores. Therefore, there has been problems in that a fluorescent layer become thick, and beam intensity distribution and visible image of beam profile become unsharp due to diffusion of ultraviolet light by scattering and scattering of fluorescent light. Therefore a conventional fluorescent material formed by powder sintering cannot be combined with the above-described optical property measurement apparatus to perform high-accuracy measurement by converting ultraviolet light to visible light.

A fluorescent light-emitting glass used to make ultraviolet light visible for measurement or observation has remarkably large thickness. As a result, allowable arrangement of the optical systems including the fluorescent light-emitting glass tends to be limited. In particular, optical path of an optical system changes depending on an absence and presence of the fluorescent light-emitting glass. Therefore, it is difficult to freely apply the fluorescent light-emitting glass to observation or measurement of a predetermined optical system through conversion of the ultraviolet light to visible light.

With regard to an optical element that has a light guide member comprising a bundle of a plurality of optical fibers, an object according to an aspect of the present invention is to provide a solution to suppress deterioration of the light guide member due to ultraviolet light irradiation.

Another object according to an aspect of the present invention is to provide a fluorescent film or a multilayer dielectric film that is not likely to unsharpen ultraviolet light and fluorescent light, facilitates accurate observation, measurement or the like of ultraviolet light utilizing the fluorescent light, and has a large degree of freedom in arrangement. Still other object according to an aspect of the present invention is to provide an optical element or an optical system provided with the fluorescent film or the multilayer dielectric film and to provide a method facilitating formation of this type of fluorescent film.

Still other object according to an aspect of the present invention is to provide an imaging unit, an optical property measuring apparatus, a method for measuring optical property, an exposure apparatus, an exposure method, and a device manufacturing method utilizing the optical element or optical system.

A fluorescent film according to a first aspect of the present invention includes a base material (host material) constituted of a material that can transmit ultraviolet light, and an activator doped in the base material, wherein the activator emits (generates) fluorescent light in the base material by irradiation of the ultraviolet light.

The above-described base material may be composed of a fluoride. The fluoride may contain unavoidable impurities.

The activator may contain a transition element or a rare earth element.

A second aspect of the present invention is a method of forming the above-described fluorescent film, including: preparing an evaporation material including the base material made of a fluoride and an activator doped in the base material; and performing resistance heating of the evaporation material, thereby vapor depositing the fluorescent film.

A third aspect of the present invention is a multilayer (plural-layer) dielectric film that includes at least one layer of the above-described fluorescent film.

An optical element according to a fifth aspect of the present invention includes the above-described fluorescent film or the multilayer dielectric film provided on a surface of an optical base member (substrate, base member).

An optical system according to a sixth aspect of the present invention is an optical system in which a plurality of optical elements is arranged, wherein at least one or all of the plurality of optical elements are constituted by the above-described optical element.

An imaging unit according to a seventh aspect of the present invention may be an imaging unit that includes the above-described fluorescent film or the multilayer dielectric film, and an image sensing device that takes an image of the fluorescent light emitted from the fluorescent film.

Alternatively, an imaging unit according to an eighth aspect of the present invention may include the above-described optical element, and an image sensing device that takes an image of the fluorescent light emitted from the fluorescent film.

The above-described imaging unit may include a light guide member that guides the fluorescent light emitted from the fluorescent film to the image sensing device.

An optical property measuring apparatus according to a ninth aspect of the present invention is an apparatus configured to measure optical properties of an optical system under examination, wherein the imaging unit may be arranged on the image plane side of the optical system and detects measurement light passing through the optical system.

In the fluorescent film according to an aspect of the present invention, the activator doped in the base material emits fluorescent light when irradiated with ultraviolet light. Therefore it is possible to measure or observe ultraviolet light utilizing the fluorescent light. Since the fluorescent material has a form of a film, it has a large degree of freedom with respect to arrangement (disposition). The fluorescent film can be easily arranged on a surface of a member irradiated with ultraviolet light. Since the fluorescent film is a thin film comprising the base material doped with the activator, it is possible to avoid problems, for example scattering of light by pores, associated with conventional fluorescent materials made of sintered powder. Therefore, unsharpening of ultraviolet light or fluorescent light due to scattering of the light can be prevented when the ultraviolet light or fluorescent light passes through a fluorescent material (fluorescent film). Thus observation or measurement of ultraviolet light can be performed accurately (precisely).

In the method of forming a fluorescent film according to an aspect of the present invention, an evaporation material is prepared by doping an activator into a base material composed of fluoride, and the evaporation material is subjected to resistance heating to thereby form a fluorescent film by vapor deposition. As a result, it is possible to form a fluorescent film while keeping the chemical composition of the evaporation material in the film. Thus formation of a fluorescent film having predetermined fluorescent properties can be facilitated.

Since the multilayer dielectric film according to an aspect of the present invention includes the fluorescent film, it is possible to perform accurate measurement, observation or the like of ultraviolet light utilizing the fluorescent light from the fluorescent film while achieving various optical properties resulting from the configuration of the multilayer dielectric film.

In the optical element according to an aspect of the present invention, since the above type of fluorescent film or the multilayer dielectric film is provided on a surface of an optical base member, fluorescent light can be generated by ultraviolet light on the surface of the optical base member, and thereby facilitates accurate measurement, observation or the like of ultraviolet light.

Where the optical element is constituted such that one or a plurality of dielectric thin films interposed between the fluorescent film and a light guide member configures a wavelength selective film that transmits fluorescent light and reflects ultraviolet light, fluorescent light emitted from the fluorescent film excited by ultraviolet light passes through the wavelength selective film and is incident upon the light guide member, and the ultraviolet light is reflected by the wavelength selective film. Therefore, deterioration of the light guide member due to ultraviolet light can be suppressed.

The optical system according to an aspect of the present invention may comprise an array of a plurality of optical elements, wherein some (one or tow or more) or all of the plurality of optical elements are constituted by the above-described optical elements. Therefore, observation and/or measurement of ultraviolet light may be performed accurately and constantly within the optical system without unsharpening of the ultraviolet light or fluorescent light due to scattering. Moreover, since the optical path does not tend to change depending on the absence and presence of the fluorescent film, it is easy to configure (constitute) a desirable optical system easily.

Since the imaging unit according to an aspect of the present invention includes the above-described fluorescent film, the multilayer dielectric film, or the optical element, and an image sensing device that takes an image of the fluorescent light from these components, it is possible to perform accurate measurement of ultraviolet light easily.

### BRIEF DESCRIPTION OF THE DRAWINGS

FIG. 1 is a schematic view of an example of an imaging unit according to a first embodiment of the present invention.

FIG. 2 is a sectional view showing a schematic configuration of an optical element according to a modified example of FIG. 1.

FIG. 3A shows a reflectance in the ultraviolet region of a multilayer dielectric film mirror according to the first embodiment of the present invention.

FIG. 3B shows the reflectance in the visible region of a multilayer dielectric film mirror according to the first embodiment of the present invention.

FIG. 4 shows the fluorescence spectrum for a fluorescent material according to the first embodiment of the present invention.

FIG. 5 is a sectional view of the schematic configuration of another example of the imaging unit according to the first embodiment of the present invention.

FIG. 6 is a schematic view of an example of an optical property measuring apparatus according to the first embodiment of the present invention.

FIG. 7 is a schematic view of another example of an optical property measuring apparatus according to the first embodiment of the present invention.

FIG. 8 shows a configuration of still another example (shearing interferometer) of an optical property measuring apparatus according to the first embodiment of the present invention.

FIG. 9 is a process diagram showing an example of a method of measuring the optical properties of FOP according to the first embodiment of the present invention.

FIG. 10 is a schematic view of an apparatus configuration in a case of measuring optical properties of an FOP according to the first embodiment of the present invention.

FIG. 11 is a schematic view showing a configuration of an example of an exposure apparatus according to the first embodiment of the present invention.

FIG. 12 is a process diagram showing an example of a method of manufacturing a semiconductor device according to the first embodiment of the present invention.

FIG. 13 is a process diagram showing an example of a method of manufacturing a liquid-crystal display element according to the first embodiment of the present invention.

FIG. 14 shows a configuration of an imaging unit according to a second embodiment of the present invention.

FIG. 15 shows a configuration of an imaging unit according to a third embodiment of the present invention.

FIG. 16 shows a modified example of the imaging unit according to the third embodiment of the present invention.

FIG. 17 is a schematic view of an exposure apparatus provided with the optical element according to the third embodiment of the present invention.

FIG. 18 is a schematic view of a modified example of an optical system provided with the optical element according to the third embodiment of the present invention.

FIG. 19 shows a result of measurement in Examples, and shows a representative example of a fluorescence spectrum for a LaF₃:Tb fluorescent film.

FIG. 20 shows a result of measurement in Examples, and shows a relationship between fluorescent intensity and Tb activator concentration of the fluorescent film.

FIG. 21 shows a result of measurement in Examples, and shows refractive index n and extinction coefficient k calculated from spectral transmittance and reflectance of a LaF₃:Tb fluorescent film.

FIG. 22 shows a result of measurement in Examples, and shows a relationship between the fluorescent intensity of light emitted by ultraviolet light of 193 nm in wavelength and a radiant flux of the ultraviolet light.

FIG. 23 shows a result of measurement in Examples, and shows the transmittance and the spectral reflectance of an optical element of Example 1 having reflection prevention films formed on both surfaces thereof.

### DESCRIPTION

Some embodiments according to the present invention will be described below.

A fluorescent film according to an embodiment of the present invention is a film that emits fluorescent light upon irradiation with ultraviolet light. The film is formed from a material that includes a base material and an activator doped in the base material. This fluorescent film is used through arranging (disposing) the film, for example, on a surface or the like of various members. There members are arranged in a position which may be irradiated by ultraviolet light or in a position irradiated by ultraviolet light. The irradiated ultraviolet light may include ultraviolet light and visible light. Alternatively, the light may only include ultraviolet light, or may be light having a wavelength of deep ultraviolet light or vacuum ultraviolet light. For example, it may be ultraviolet laser light from a KrF excimer laser (wavelength 248 nm), an ArF excimer laser (wavelength 193 nm), or the like.

The base material of the fluorescent film is formed from a material that transmits ultraviolet light. This material may be suitably selected according to the irradiated ultraviolet light. A fluoride may be suitably used as the base material. A fluoride enables transmission of visible light. Many fluorides enable transmission of light in wavelength region which is transmitted by oxides. For this reason, a fluoride is indispensable material particularly in a fluorescent film and an optical element for a light of vacuum ultraviolet region. This type of fluoride is also transparent to emitted fluorescent light and enables effective utilization of the fluorescent light.

Use of a fluoride as the base material of the fluorescent material has other advantages. The fluorescent material absorbs ultraviolet light with the base material or with activator ions as described hereafter, and thereby activator ions become excited. The excited activator ions transit to an luminescent level through non-radiative transition (many activator ions lose energy by exciting phonons in the base material), and then transit from that level to a ground level and emit light. This luminescence transition also competes with the non-radiative transition due to phonon excitation in the base material. The probability of non-radiative transition increases with increasing phonon energy in the base material. A fluoride has a low phonon energy and a low probability of non-radiative transition. This physical property enables suppression of loss of light energy absorbed by the fluorescent material as heat. This is an advantageous property that contributes to improvement of light durability of the fluorescent film.

The fluoride may be selected from one of the group, or a mixture or compound of two or more of the group consisting of neodymium fluoride (NdF₃), lanthanum fluoride (LaF₃), gadolinium fluoride (GdF₃), dysprosium fluoride (DyF₃), lead fluoride (PbF₂), hafnium fluoride (HfF₂), magnesium fluoride (MgF₂), yttrium fluoride (YF₃), aluminum fluoride (AlF₃), sodium fluoride (NaF), lithium fluoride (LiF), calcium fluoride (CaF₂), barium fluoride (BaF₂), strontium fluoride (SrF₂), cryolite (Na₃AlF₆), and chiolite (Na₅Al₃F₁₄).

The mixture or compound of the fluoride includes a solid solution mixed crystal of lanthanum fluoride and calcium fluoride (CaₓLa₁₋ₓF₃₋ₓ wherein, 0<x<1. Hereinafter referred to as “CLF”), and a solid solution mixed crystal of lanthanum fluoride and yttrium fluoride (CaₓY₁₋ₓF₃₋ₓ).

A method of manufacturing the fluoride may be suitably selected. For example, a hydrothermal synthesis may be used to manufacture the fluoride as a fluoride ceramic. In a hydrothermal synthesis method, particulate fluoride (fluoride particles) is prepared by reacting a compound (for example, acetate) of a cationic component of the fluoride with a fluorine compound such as hydrofluoric acid in an aqueous solution. After forming the particulate fluoride into a dried body or pressed molded body, sintering is executed at a temperature of 800 to 1000° C. to thereby form a fluoride ceramic.

A fluoride composed of a solid solution mixed crystal may be prepared as a fluoride ceramic using the hydrothermal synthesis method in a similar manner as described above. In this case, particulate fluorides are synthesized separately with respect to each cationic component to thereby prepare a suspension of each particulate fluoride. Then both suspensions are mixed using a wet process to obtain a particulate mixture. This particulate mixture is formed into a dried body or press molded body, and sintered at a temperature of 800 to 1000° C. to thereby form a fluoride ceramic.

The fluoride may be suitably selected as one from the group consisting of lanthanum fluoride (LaF₃), yttrium fluoride (YF₃), CLF, and gadolinium fluoride (GdF₃). As clearly shown by the Example described below, these fluorides facilitate increase intensity of fluorescent light generated by irradiation of short-wavelength ultraviolet light.

The activator of the fluorescent film emits fluorescent light when irradiated with ultraviolet light in a state being doped in the base material. The activator may be suitably selected according to the ultraviolet light to be irradiated. For example, the activator may include transition elements or rare earth elements. Where the activator is selected from transition elements or rare earth elements, it is considered that the atoms or ions of the transition element or rare earth element diffuse into the microcrystals of the base material, substitute the cationic sites of the base material, and/or enter into interstitial spaces within the crystal lattice to thereby function as an activation component.

The transition element or rare earth element includes europium (Eu), terbium (Tb), praseodymium (Pr), samarium (Sm), dysprosium (Dy), cerium (Ce), holmium (Ho), erbium (Er), or ytterbium (Yb). It is preferred that the activator is selected from one or two or more of the group consisting of europium (Eu), terbium (Tb), and praseodymium (Pr). As clearly shown by the Examples described below, these elements facilitate an increase in the intensity of the fluorescent light generated by irradiation of short-wavelength ultraviolet light.

The concentration of the activator in the base material is preferably greater than or equal to 1% and less than or equal to 10% in atomic percent concentration relative to the cationic component of the base material. For example, where the base material is composed of lanthanum fluoride (LaF₃) and the activator is composed of terbium (Tb), the concentration of terbium (Tb) relative to lanthanum (La) in an atomic percent concentration is particularly preferably greater than or equal to 8% and less than or equal to 10%. Where the concentration of the activator is excessively low, it is difficult to obtain sufficient fluorescence. On the other hand, where the concentration of the activator is excessively high, a concentration quenching phenomenon may occur or the concentration reaches solubility limit at which the activator cannot be further dissolved in the fluoride base material.

A material of the fluorescent film may be composed of the base material and the activator. For example, it may be composed only of the above-described fluoride and the activator. The fluoride forming the base material may contain unavoidable impurities. In addition to the base material and the activator, the material of the fluorescent film may contain other components within a range that allows the fluorescent film to emit fluorescent light due to incident ultraviolet light.

A fluorescent film according to an embodiment of the present invention is a film constituted of the above-described material. At least, it is required that the activator is doped in the base material in the fluorescent film. Formation of the film of such a constitution may include forming a film using a material in which the activator is doped preliminarily in the base material. Alternatively, the fluorescent film may be formed using the base material and the activator formed to separate materials and forming the film while doping the activator into the base material.

Preparation of the material in which the activator is doped in advance into the base material is enabled using the following method. For example, in the preparation of the fluoride base material using the above-described hydrothermal synthesis method, a raw material powder may be prepared by mixing an aqueous solution of acetic acid salt of the activator into a suspension of the particulate fluoride or the particulate fluoride mixture. Then a fluoride ceramic is formed by sintering a dried body or a pressed molded body of the raw material powder to thereby prepare a material in which the activator is doped in the base material. During sintering in the above-described manufacturing method, it is considered that the components of the activator such as the rare earth metal ions or the like diffuse into the microcrystals of the base material to thereby substitute the sites of cationic components of the base material, and/or enter into the interstitial spaces in the lattice to thereby become activated. In the hydrothermal synthesis, the activator may be added in a form other than the aqueous solution of the acetic acid salt. As an alternative to the acetic acid salt, it is possible to use various salts including an organic acid salt such as a lactate, an oxalate, an ascorbate, an alginate, a benzoate, a carbonate, a citrate, a gluconate, a pantothenate, a salicylate, a stearate, a tartrate, a glycerate, a trifluoroacetate, and the like, or an inorganic acid salt such as a chloride, a hydroxide, a nitrate, a sulfate or the like.

Formation of a film using a material comprising the base material and activator doped in the base material may employ various known thin-film formation methods. The fluorescent film may be suitably formed using a vapor-phase film-forming method. For example, homogeneous thin film may be easily obtained, and film-thickness may be easily controlled by the vapor-phase film-forming method. Preferably, the film may be formed using a vacuum vapor deposition method to obtain a coating (film) with satisfactory optical properties. Preferably, a fluorescent film may be formed by preliminarily preparing an evaporation material in which the base material is doped with the activator, and subjecting the evaporation material to resistance heating to thereby vapor deposit the fluorescent film.

In a vapor phase deposition method such as a sputtering, use of an evaporation material (sputtering target) composed of multi-component substance tends to result in difference between the chemical composition of the evaporation material and the chemical composition of the formed thin film. However, it was confirmed that a fluorescent film could be formed while substantially maintaining the chemical composition of the evaporation material in the film by forming the film using vacuum deposition method through resistance heating, where the evaporation material is composed of a base material such as lanthanum fluoride and an doped activator such as terbium or europium. Since film thickness can be simply controlled by adjusting the conditions or duration of vapor deposition, formation of a fluorescent film having a desired film thickness and desired optical properties is extremely simple.

Formation of a fluorescent film while doping the base material with the activator may be performed by respectively preparing an activator and raw-base material composed of UV-permeable material, and performing vapor deposition of the base material and the activator simultaneously using a vapor-phase film formation method, preferably a vacuum vapor deposition method. For example, a base material such as lanthanum fluoride and a fluoride compound such as terbium fluoride containing terbium as the activator may be simultaneously subjected to vapor deposition while adjusting the vapor deposition ratio to thereby form a thin film in which the base material is doped with the activator.

A thickness of the fluorescent film can be set in accordance with the irradiated ultraviolet light or intended use of the fluorescent film. As the film thickness increases, more ultraviolet light becomes visible and thereby increases the intensity of the fluorescent light. On the other hand, small thickness is preferred in a high-accuracy optical system, since the optical path may be changed by the presence of the fluorescent film where the film has large thickness. The film thickness may be determined based on the optical properties. When the film is excessively thin, it is difficult to generate sufficient fluorescent light. In such a case, a material generating fluorescent light of high intensity may be selected, or a plurality of fluorescent films may be stacked to thereby increase the intensity of the fluorescent light. It is preferred to control the thickness of each layer of the fluorescent film to be less than or equal to substantially half of the wavelength of the irradiated ultraviolet light or the designed central wavelength. For example, in an optical system using short-wavelength ultraviolet light, the film thickness of the fluorescent film may be less than or equal to 180 nm, or may be less than or equal to 125 nm, In particular. in an optical system utilizing vacuum ultraviolet light, the film thickness of the fluorescent film may be less than or equal to 100 nm, or may be less than or equal to 80 nm. For example, in a laser optical system using an ArF excimer laser (wavelength 193 nm), the film thickness may be less than or equal to 100 nm. When a sufficient fluorescent light intensity is obtained, a fluorescent film with the above film thickness may be used as a single layer. Alternatively, a fluorescent film with the above film thickness may be stacked, to thereby form, for example, a fluorescent film with a total film thickness of less than or equal to 3 μm or less than or equal to 1 μm.

According to the above-described fluorescent film, since an activator doped in a base material generates fluorescent light upon irradiation of the base material with ultraviolet light, the fluorescent light can be used for accurate measurement, observation or the like of ultraviolet light.

Since the fluorescent material is formed as a film, a substantial space is not required for its arrangement. Since the film has high degree of freedom in arrangement, the fluorescent film may be easily arranged on the position irradiated with ultraviolet light on a surface of an optical member or the like. Since the fluorescent film is a thin film in which the activator is doped in the base material, in contrast to a fluorescent material layer in the form of sintered powder, it is possible to prevent unsharpening of fluorescent light or ultraviolet light due to scattering when the light passes through the fluorescent film. Therefore, it is possible to perform measurement or observation of ultraviolet light accurately.

One of definitive differences between the fluorescent film and conventional fluorescent powder or fluorescent glass is that the fluorescent film can be used as an optical thin film. In other words, it is possible to impart a function of fluorescent light emission (fluorescence function) in an optical system while maintaining an configuration of the optical system unchanged, by forming the fluorescent film according to an embodiment of the invention on a surface of an optical element or the like included in the optical system.

An optical system comprising an array of a plurality of optical elements is required to include an optical element having high reflectance or high transmittance in ultraviolet wavelength region so as to introduce fluorescent light and/or ultraviolet light except for the light consumed in fluorescence to another optical element by transmission or reflection of the light.

However, in a conventional fluorescent material, for example composed of fixed fluorescent powder, the reflected or transmitted light also includes scattered-light components resulting from scattering in all directions in addition to components having an angle according to the principle of reflection or refraction with respect to the incident light. The reflectance or transmittance of light including such scattered light varies as a result of the agglomeration density and the particle-diameter distribution of the fluorescent powder. Therefore, conventional fluorescent materials composed of fluorescent powder could not be utilized as an optical thin film provided to an optical system because of disturbance of optical path of the optical system due to scattering of incident ultraviolet light and fluorescent light.

Where a fluorescent material is composed of a conventional fluorescent glass, it is possible to utilize transmitted light, that is, light of a wavelength other than the absorption wavelength of the glass. The transmittance of fluorescent glass can be controlled with relatively high accuracy by quality control of the glass corresponding to quality control of an optical glass. However, conventional fluorescent glass has a thick shape. When the fluorescent glass is inserted into a preexisting optical system, an optical path of the system is changed to unignorable level due to refraction by the fluorescent glass.

The fluorescent film according to an embodiment of the present invention is a film that is formed from a material in which a base material is doped with an activator Therefore, scattering of incident ultraviolet light and generated fluorescent light is prevented. Since it is formed as a film, even when fluorescent film is arranged in the optical path of an optical system, change to the optical path of ultraviolet light and fluorescent light is not likely to occur. As a result, the fluorescent film according to an embodiment of the present invention can be formed on an optical element while maintaining the optical system in the same state to thereby impart a fluorescence function in the optical system.

Another difference between the fluorescent film according to an embodiment of the present invention and conventional fluorescent powder or fluorescent glass is its applicability for observation and measurement of light in vacuum ultraviolet region. For example, it is possible to effectively measure or observe light at a wavelength of less than or equal to 200 nm, including light having a wavelength of 193 nm generated by an ArF excimer laser, light having a wavelength of 157 nm that is generated by an F₂ excimer laser, and the like. The fluorescent film can be used for observation or measurement of other short-wavelength ultraviolet light, for example, i-line having a wavelength of 365 nm or light at a wavelength of 248 nm generated by a KrF excimer laser.

To make ultraviolet light visible in a laser optical system using vacuum ultraviolet light, a conventional fluorescent material composed of fixed fluorescent powder will undergo serious deterioration and can only be used for a short time, and conventional fluorescent light emitting glass will absorb a large amount of the vacuum ultraviolet light and deteriorate over time as a result of the absorption of ultraviolet light. Therefore, even if temporary use is possible, constant use by arrangement of these conventional fluorescent materials in an optical system has not been possible.

On the other hand, in an embodiment of the present invention, since a fluorescent material may be constituted of a film in which the base material is a fluoride substance and the activator contains a transition metal or rare earth metal, it is possible to achieve clear and high transmittance of light from visible light to vacuum ultraviolet light, and improved laser resistance. Therefore measurement and observation of ultraviolet light is possible even in vacuum ultraviolet light region such as a wavelength of 193 nm.

The fluorescent film according to an embodiment of the present invention can be used as a single layer. It is possible to use the fluorescent film as a constituent of multilayer dielectric film (plural layer dielectric film) that has a multilayered structure (dielectric stacked film) formed by stacking of a plurality of layers. Where the fluorescent film is used in a multilayer dielectric film, the fluorescent film according to an embodiment of the present invention can be used as a part or the whole of the multilayer dielectric film in which a plurality of dielectric thin films is stacked. In other words, of the plurality of the dielectric layers forming the multilayer dielectric film, the fluorescent film according to an embodiment of the present invention may constitute one layer, or the fluorescent film according to an embodiment of the present invention may constitute two or more layers.

Where a fluorescent film and a dielectric thin film other than a fluorescent film are stacked to constitute the multilayer dielectric film, the dielectric thin film other than a fluorescent film may be a film formed from various types of materials. It is preferred that the film is formed from a material that has sufficient durability to irradiated ultraviolet light. The dielectric thin film is suitably formed from a material that can be used as a base material for the above-described fluorescent film. For example, the respective layers of the multilayer dielectric film may be a film formed from a fluoride in the above-described selections for the base material. For example, lanthanum fluoride (LaF₃), gadolinium fluoride (GdF₃), magnesium fluoride (MgF₂) or the like may be used. In addition, silica (SiO₂), aluminum fluoride (AlF₃) or the like may be used. The material forming each dielectric thin film that configures the multilayer dielectric film may be respectively the same or may be different. In other words, a plurality of a single type of dielectric thin film may be stacked to configure the multilayer dielectric film, or a plurality of two or more types of dielectric thin films may be stacked to configure the multilayer dielectric film. For example, two types of dielectric thin films having different refractive indexes may be alternatively stacked to form the multilayer dielectric film.

Preferably, the multilayer dielectric film is configured to obtain various types of optical properties by a part or the whole of the multilayered structure. For example, it is possible to configure the multilayer dielectric film as a wavelength selective film that reflects ultraviolet light and transmit fluorescent light, or as an antireflection film that prevents reflection of light of a predetermined wavelength.

In this case, the multilayer dielectric film may be formed by constituting a stacking structure by stacking dielectric thin films such that desired optical properties (for example, wavelength selective properties, or antireflection properties) are obtained, and further stacking the fluorescent film according to an embodiment of the present invention separately to thereby form the multilayer dielectric film. In other words, the multilayer dielectric film may be configured to include at least one fluorescent film layer, and a stacked film having a wavelength selective property or antireflection property formed from a plurality of dielectric layers. In this manner, it is possible to make a thickness of the fluorescent film provided separately to the stacking structure thicker than the film thickness of the dielectric thin films constituting a stacking structure, and thereby more intense fluorescent light can be obtained. In this case, the uppermost layer of the multilayer dielectric film may be constituted of the fluorescent film.

The fluorescent film according to the present invention may be used as a part or the whole of the dielectric thin film configuring the stacking structure that obtains a desired optical properties. In other words, a function of emitting fluorescent light may be imparted to the dielectric thin film configuring the multilayer dielectric film. In this manner, fluorescent light may be obtained by configuring a multilayer dielectric film having a desired optical properties. Therefore, the multilayer dielectric film may be obtained in the same manner as a multilayer dielectric film that does not emit fluorescent light. In that case, the intensity of fluorescent light can be increased by forming more of the thin films of fluorescent films in the multilayer dielectric films.

As described above, where at least one of the dielectric thin films is constituted of fluorescent film in the multilayer dielectric film constituted by stacking a plurality of dielectric thin films, it is possible to obtain a fluorescence in addition to various optical properties. Moreover, it is possible to prevent changes to the optical path or unsharpening resulting from scattering or the like of the ultraviolet light or fluorescent light during observation or measurement of the ultraviolet light utilizing the fluorescent light. Therefore, it is possible to perform observation and measurement of the ultraviolet light with high accurately.

The above-described multilayer dielectric film or the fluorescent film according to an embodiment of the present invention may be arranged as a single layer fluorescent film or as a multilayer dielectric film constituted of a plurality of dielectric layers in various members that are irradiated with ultraviolet light.

For example, an optical element can be configured by providing the fluorescent film or the multilayer dielectric film on an incident surface or exit surface of various types of optical base members (substrates). The optical base member may be in a form of window member, lens, prism, FOP or the like. Material of the optical base member may be selected from a material that transmit ultraviolet light, or from a material that does not transmit the ultraviolet light. The material of optical base member may be selected from an optical glass, an optical ceramic, an optical crystal, an optical plastic, an optical fiber (for example when using FOP), or the like. Optical glass may be used as an optical base member enabling transmission of light of a wavelength ranging from visible light to near ultraviolet region. Calcium fluoride or synthetic silica glass may be used as an optical member enabling transmission of light in vacuum ultraviolet region. The above-described optical element can be used for example as a component of various types of optical systems, an apparatus that makes ultraviolet light visible, a beam, profiler, a beam checker or the like.

The fluorescent film or the multilayer dielectric film may be provided in various types of base members that cannot transmit ultraviolet light or fluorescent light. For example, a single layer fluorescent film or the multilayer dielectric film may be provided on a opaque covering member or a wall surface, or the like.

The fluorescent film or the multilayer dielectric film, or an optical element provided with the fluorescent film or the multilayer dielectric film can be disposed to a light receiving surface of an image sensing device that can image (take an image of) fluorescent light or an image sensing device that can image ultraviolet light to thereby configure an imaging unit.

For example, an imaging unit may be constituted by using a fiber optic plate (FOP) configured from a bundle of a plurality of optical fibers as an optical element, arranging the fluorescent film or the multilayer dielectric film on the FOP such that fluorescent light emitted from the fluorescent film is guided by the FOP to the light receiving surface of the image sensing device. In this case, a wavelength selective film formed from the multilayer dielectric film may be provided between the fluorescent film and the FOP to thereby reflect ultraviolet light.

The fluorescent film or the multilayer dielectric film may be provided on the light receiving surface of the image sensing device.

It is preferred that the film thickness of each dielectric layer configuring the multilayer dielectric film is substantially less than or equal to ½ of the wavelength of the irradiating light (for example, ultraviolet light) or substantially less than or equal to ½ of the designed central wavelength.

The total film thickness of the multilayer dielectric film can be selected according to the use thereof. When the fluorescent film or the multilayer dielectric film is formed on an FOP, the total film thickness is preferably less than or equal to the diameter of the respective optical fibers that constitute the FOP. For example, the total thickness may be less than or equal to 3 μm.

The fluorescent film or the multilayer dielectric film provided in various members may be covered (e.g., coated) with other films from the outer side. For example, the fluorescent film or the multilayer dielectric film may be covered from an outer side by a protective film having at least one of a water-resistant property and a water-repellant property to thereby improve durability.

The above-described imaging unit may be used in the configuration of an optical property measuring apparatus.

For example, in a configuration of measurement apparatus examining optical properties of an optical system, an imaging unit that includes the above-described fluorescent film, a light guide member (for example, a FOP), and an image sensing device arranged to enable imaging of fluorescent light from a fluorescent film may be arranged on an image plane side of an optical system under examination, to thereby detect measurement light passing through the optical system with the imaging unit.

The imaging unit of the optical property measuring instrument may be configured to include a fluorescent film and a wavelength selective film. For example, a multilayer dielectric film including the fluorescent film and the multilayer dielectric film having the above-described wavelength selective function may be arranged on the incident surface side of the light guide member. For example, the fluorescent film may be arranged on the incident surface side of the light guide member interposing the wavelength selective film such that the wavelength selective film transmits fluorescent light and reflects light of a predetermined wavelength (for example, ultraviolet light).

The above-described optical property measuring apparatus may be provided with an illumination optical system that illuminates (irradiates) light (measurement light) onto the optical system under examination. Alternatively, the above-described optical property measuring apparatus may be provided in an optical apparatus having an illumination optical system to thereby measure the optical property of the optical system in a predetermined position.

The above-described optical property measuring apparatus may include a first periodic pattern arranged on an object plane of the optical system under examination, and a second periodic pattern arranged on an incident surface or exit surface of the light guide member such that a moire fringe formed by the first periodic pattern and the second periodic pattern may be detected by the image sensing device. By using this type of apparatus, it is possible to measure distortion in an optical system under examination based on the detected moire fringe.

The above-described optical property measuring apparatus may include a pinhole arranged on the object plane of the optical system under examination, and a microlens array arranged between the image plane of the optical system and the incident surface of the imaging unit such that a point image collected by the microlens array may be detected by the imaging unit. This type of optical property measuring apparatus enables measurement of wavefront aberration in the optical system under examination.

The above-described optical property measuring apparatus may further include a pinhole, a relay lens, a microlens array, and a detector (detection device), wherein the pinhole may be arranged on the object plane of the optical system under examination; the imaging unit may includes a wavelength selective film between the light guide member and the fluorescent film and is arranged such that an incident surface of the light guide member is inclined by 45 degrees from an optical axis of the optical system under examination; the relay lens may be arranged between the image plane of the optical system and the incident surface of the imaging unit; the detector may be arranged such that an incident surface of the detector is perpendicular to the image plane of the optical system; the micro lens array may be arranged between the incident surface of the imaging unit and the detection device.

In the above-described apparatus, the relay lens may convert a measurement light diffracted by the pinhole into parallel light. The wavelength selective film of the imaging unit may transmit fluorescent light generated in the fluorescent film and forms reflected light by reflecting the measurement light passing through the fluorescent film in an direction orthogonal to the incident direction. The image sensing device of the imaging unit may detect fluorescent light guided by the light guide member. The detection device may detect the reflected light condensed by the micro lens array.

By using the optical property measuring apparatus of the above-described configuration, it is possible to calculate a numerical aperture of the optical system under examination by measurement of the intensity distribution of measurement light with the image sensing device of the imaging unit. At the same time, it is possible to calculate the wavefront aberration in the optical system under examination based on the amount of deviation in the position of the point image collected by the microlens array.

The wavelength selective film has the function of transmitting light of a predetermined wavelength and reflect and/or absorb light of a predetermined wavelength. The multilayer dielectric film according to an embodiment of the present invention may be used as the wavelength selective film. For example, the wavelength selective film may be a film that transmits visible light of a predetermined wavelength and reflects ultraviolet light of a predetermined wavelength.

The optical property measuring apparatus may include a pinhole arranged on the object plane of the optical system under examination, and a diffraction grating arranged on the image plane of the optical system under examination such that an interference pattern formed by the diffraction grating may be detected by the imaging unit. According to this type of optical property measuring apparatus, it is possible to measure the wavefront aberration of the optical system under examination.

The optical property measuring apparatus having the above-described configurations may be applied to measurement of optical properties of various types of optical systems. For example, where the apparatus is combined with an exposure apparatus that exposes a light onto a photosensitive base material (substrate) via a predetermined pattern, optical properties of the exposure system may be measured by the optical property measuring apparatus and wavefront aberration or distortion may be corrected to thereby enable accurate exposure. By using this type of accurate exposure apparatus, it is possible to improve the performance of various types of devices (including for example, semiconductor devices, image sensing devices, liquid-crystal display devices, thin-film magnetic heads and the like) formed by exposure processing.

Next, various actual embodiments using a fluorescent film or a multilayer dielectric film according to embodiments of the present invention will be described.

### First Embodiment

### A First Configuration of an Optical Element and an Imaging Unit

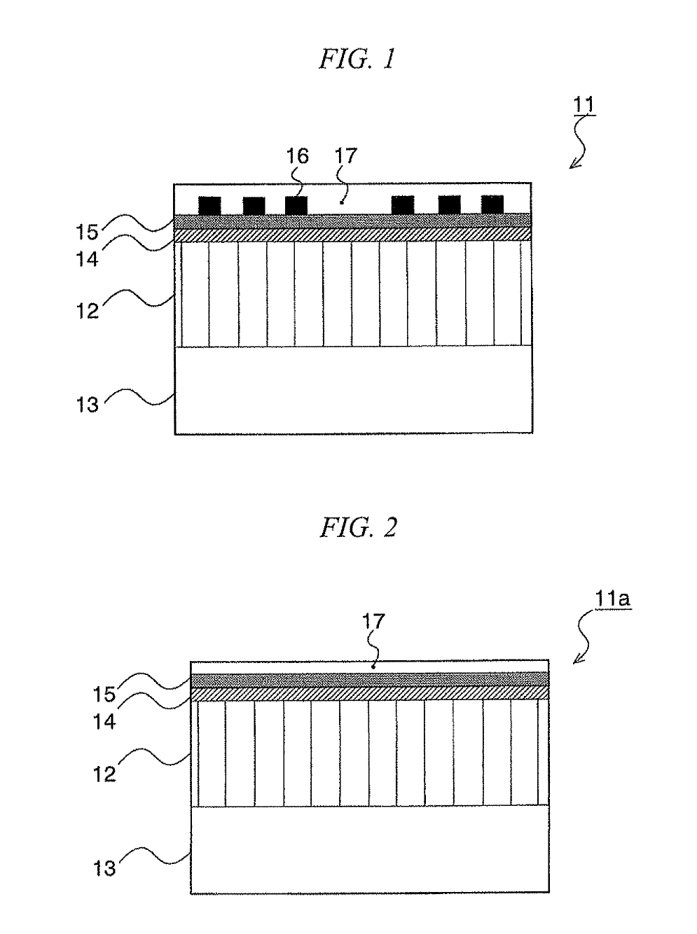

FIG. 1 is a sectional view of an example of an imaging unit provided with an optical element. For example, the imaging unit can be used by being incorporated into an optical property measuring apparatus that measures the optical property of a projection optical system of an exposure apparatus.

The imaging unit 11 shown in FIG. 1 includes a FOP 12 and an image sensing device 13. The FOP 12 is an optical base member made by bundling a plurality of optical fibers at a fixed interval, and forming the bundle into a plate shape. The FOP 12 is constituted of a material that transmit visible light but does not transmit ultraviolet light. Each optical fiber in the FOP 12 is disposed as an array extending in the vertical direction in FIG. 1. A light flux incident from the incident surface (upper side of FIG. 1) of the FOP 12 propagates through each optical fiber and guided to the exit surface side of the FOP 12.

In ascending order, a wavelength selective film 14, a fluorescent film 15, a periodic pattern 16, and a protective film 17 are stacked on an incident surface (upper surface in FIG. 1) of the FOP 12. On the other hand, an image sensing device 13 is mounted on the exit surface (lower surface in FIG. 1) of the FOP 12. To avoid a reduction in the lateral resolution of the FOP 12, the total thickness of the wavelength selective film 14 and the fluorescent film 15 formed on the incident surface of the FOP 12 is set to less than or equal to the diameter of each optical fiber in the FOP 12.

The wavelength selective film 14 is formed between the FOP 12 and the fluorescent film 15 and has properties of transmitting visible light and reflecting ultraviolet light. As an example, the wavelength selective film 14 may be configured as a multilayer dielectric film mirror.

The fluorescent film 15 is exited by the ultraviolet light and emits fluorescent light, and has a function of converting the ultraviolet measurement light to visible measurement light.

A periodic pattern 16 is formed on the surface of the fluorescent film 15. The periodic pattern 16 is a line and space pattern in which a shading portion covering the fluorescent film 15 and a transmission portion fanning an aperture are repeated regularly in an array.

A protective layer 17 covers the shading portion of the periodic pattern 16 and the surface of the fluorescent film 15 (the transmission portion of the periodic pattern 16). The protective layer 17 has at least one of a water-resistant property and a water-repellant property. The protective layer 17 has a function of suppressing permeation of liquids and protecting the films of the lower layers from air and moisture.

The image sensing device 13 has a light receiving surface having a two-dimensional array of a plurality of light receiving elements (not shown), and the light receiving surface of the image sensing device 13 is made contact to the exit surface of the FOP 12. In this embodiment, a cover glass or filter is not mounted on the image sensing device 13 but rather the FOP 12 is directly fixed to the light receiving surface of the image sensing device 13 by an adhesive or the like.

In a modified example of the imaging unit shown in FIG. 1, the periodic pattern may be formed on the emission surface side of the FOP (omitted from the figures). In a modified example of the imaging unit shown in FIG. 1, the imaging unit may be configured such that the periodic pattern is not formed on the optical element (refer to FIG. 2). The imaging unit 11a shown in FIG. 2 can function in the same manner as the imaging unit 11 shown in FIG. 1 since a plate on which the periodic pattern is formed is detachably mounted on the optical element. Corresponding constituents in FIG. 2 and FIG. 1 are expressed by the same symbols to omit repeated explanation.

The operation and effect of the imaging unit 11 according to the embodiment shown in FIG. 1 will be described below. When short-wavelength ultraviolet light (ArF excimer laser, KrF excimer laser, or the like) is irradiated onto the imaging unit 11 from the upper portion of FIG. 1, the short-wavelength ultraviolet light becomes incident upon the fluorescent film 15 through the transmission portion of the periodic pattern 16. The fluorescent film 15 emits fluorescent light in the visible region in response to the intensity of the incident short-wavelength ultraviolet light. The fluorescent light is transmitted through the wavelength selective film 14 with almost no attenuation to become incident upon the FOP 12. The measurement light (fluorescent light) emitted from the FOP 12 is measured by the image sensing device 13. On the other hand, the short-wavelength ultraviolet light passing through the fluorescent film 15 is almost completely reflected by the wavelength selective film 14.

According to this configuration of the present embodiment, since the incidence of short-wavelength ultraviolet light to the FOP 12 is almost completely cut-off by the wavelength selective film 14, deterioration of the FOP 12 as a result of the short-wavelength ultraviolet light can be suppressed thereby resulting in a large improvement in the durability and reliability of the imaging unit 11. On the other hand, since ultraviolet measurement light is converted to visible fluorescent light by the fluorescent film 15 and passes through the wavelength selective film 14, accurate measurement using fluorescent light is enabled by this configuration of the present embodiment.

In the present embodiment, since the short-wavelength ultraviolet light incident from the light source and the short-wavelength ultraviolet light reflected by the wavelength selective film 14 both participate in the generation of fluorescent light, strong-intensity fluorescent light can be relatively easily produced by the fluorescent film 15, and therefore enables a reduction in the thickness of the fluorescent film 15. Since the fluorescent film 15 in the present embodiment uses a fluoride as the base material, the fluorescent film 15 has a high durability in relation to short-wavelength ultraviolet light. Since the fluorescent film 15 in the present embodiment is formed using a vacuum vapor deposition method, there is low scattering of fluorescent light in comparison to a fluorescent material made by coating a mixture of fluorescent particles and a binder. Therefore, it is possible to obtain a fluorescent film 15 with superior optical property.

In the present embodiment, deterioration of the fluorescent film 15 is suppressed by covering the fluorescent film 15 and the periodic pattern 16 by the protective film 17. For example, in the case in which the imaging unit is used in an optical property measuring apparatus mounted in an immersion exposure apparatus, a liquid such as water fills the space between the optical system under examination (for example, a projection optical system of the exposure apparatus) and the FOP 12. The fluorescent film 15 in the present embodiment is protected from the liquid by the protective film 17. In the case where ultraviolet light is irradiated in air, oxides or hydroxides of fluoride compounds are produced at the interface of air and the fluorescent film 15 and cause deterioration of optical properties. In the present embodiment, such deterioration of the fluorescent film 15 is suppressed by the protective film 17. Where the protective film 17 has a sufficient film strength, pollution on the surface can be easily removed by rubbing.

### Embodiment of Manufacturing an Optical Element

An example of manufacturing the optical element portion of the imaging unit 11 shown in FIG. 1 will be described below as an embodiment The FOP 12 used in this embodiment was a product having an optical fiber diameter of 6 μm manufactured by the SCHOTT AG. Both end faces of the FOP 12 were subjected to optical polishing and were washed before film formation.

Next a multilayer dielectric film mirror was formed as a wavelength selective film 14 on the incident surface side of the FOP 12. The multilayer dielectric film mirror in the present embodiment had a designed central wavelength of 193 nm, and was formed by vapor deposition of a plurality of alternate layers of lanthanum fluoride (LaF₃) and magnesium fluoride (MgF₂). Each layer of lanthanum fluoride layers and magnesium fluoride layers had an optical thickness of λ/4 of the respective designed central wavelengths (when the designed central wavelength is taken to be λ, ¼ of that value), and was formed as 42 layers stacked alternately from the FOP 12 side.

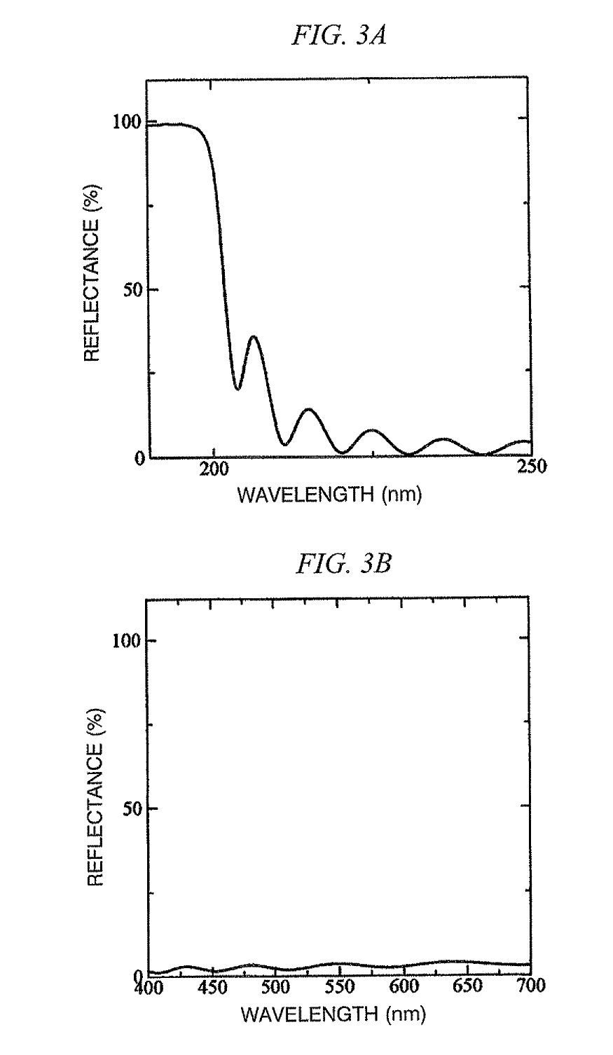

FIG. 3A and FIG. 3B show the reflectance of the multilayer dielectric film mirror according to the present embodiment. The multilayer dielectric film mirror had a reflectance of greater than or equal to 98% in the 193 nm wavelength band which was the designed central wavelength, and had a reflectance of less than or equal to 5% in the wavelength region (band) ranging from 400 nm to 700 nm. Thus the multilayer dielectric film mirror reflected almost all ultraviolet light from an ArF excimer laser and allowed transmission of almost all visible fluorescent light produced by the fluorescent film as described below.

Next, the fluorescent film 15 was formed by vacuum vapor deposition of a fluorescent material on the surface of the multilayer dielectric film mirror. A raw material used in the formation of the fluorescent film 15 was a fluorescent material synthesized of lanthanum fluoride (LaF₃) as a base material and a rare earth metal, europium (Eu) as an activator.

In the preparation of the fluorescent material, microcrystal particles of lanthanum fluoride were mixed with an aqueous solution of europium acetate to thereby obtain a raw material powder using a hydrothermal synthesis method. In the present embodiment, the concentration of the activator (Eu/La ratio) was approximately 5 molar %. A hydrothermal synthesis method disclosed in Japanese Patent Application First Publication No. 2006-206359 may be utilized as an example of a production process for the above-described raw material powder.

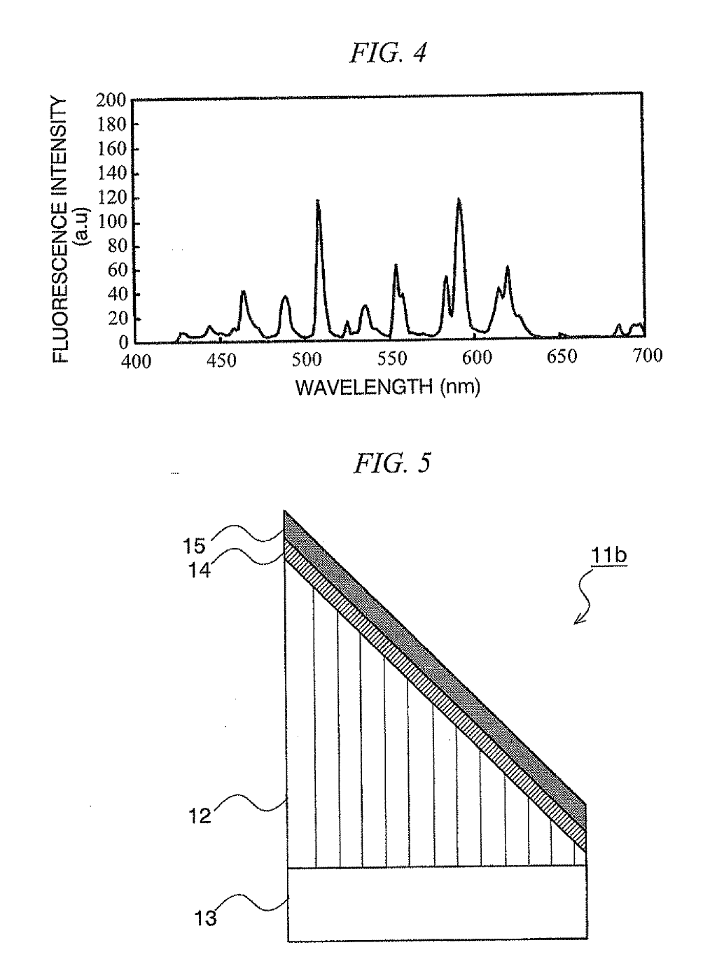

A fluorescent-material sintered body was obtained by press-molding the raw material powder into a pellet, and heating the pellet at a temperature of 800° C. for one hour in an electric furnace. It is considered that during the sintering process, europium ions diffuse into the microcrystals of the lanthanum fluoride, undergo substitution at a lanthanum site, take a trivalent state, and are activated. FIG. 4 shows the fluorescent spectrum of the fluorescent material in the present embodiment. It is understood that the fluorescent film 15 in the present embodiment emit orange to red fluorescent light of a wavelength of about 600 nm as a result of excitation by incident ultraviolet light.

Thereafter, the above-described fluorescent-material sintered body was disposed on a Mo boat in a vacuum vapor deposition apparatus, and vacuum vapor deposition of the fluorescent film 15 onto the surface of the multilayer dielectric film mirror was performed by resistance heating of the fluorescent-material sintered body. In the present embodiment, the film thickness of the fluorescent film 15 was 500 nm. During vacuum vapor deposition, the FOP 12 was heated to 300° C. It is possible to improve film strength of the lanthanum fluoride film by heating of the FOP 12. In addition, lanthanum fluoride particles in the thin film had satisfactory crystallinity by the heating of the FOP 12, thereby facilitating emission of fluorescent light.

Before film deposition of the fluorescent film 15, it is preferred to maintain a cleanest possible state on the surface of the multilayer dielectric film mirror. For example, when using a vacuum vapor deposition apparatus provided with three or more vapor deposition sources for resistance heating, the film deposition process for the fluorescent film 15 and the multilayer dielectric film mirror could be continuously performed to thereby enable formation of the fluorescent film 15 on the clean mirror surface. Where deposition of the multilayer dielectric film mirror is performed using a method other than vacuum vapor deposition, or where the above-described deposition source cannot be prepared, the FOP 12 can be inserted and removed in a clean environment such as a clean room, or the surface of the mirror may be washed or wiped before deposition of the fluorescent film 15.

Next, a periodic pattern 16 made of a chromium thin film was formed on the surface of the fluorescent film 15. In the present embodiment, after placing the surface of the fluorescent film 15 into a clean state by washing or wiping, a chromium thin film was formed on the surface of the fluorescent film 15 by sputtering. Thereafter, a photoresist was coated by spincoating, and the photoresist was exposed using a photomask having a pattern of the periodic pattern 16. Then developing was performed by an etching process to thereby remove the chromium thin film of the transmission portion allowing transmission of ultraviolet light. In this manner, a line and space pattern 16 which periodically repeats the shading portion and the transmission portion is formed on the fluorescent film 15. The pitch of the shading portion and the transmission portion in the pattern according to the present embodiment was 0.5 μm.

Finally, a water resistant film was formed as a protective layer 17 on the uppermost layer of the FOP 12. In the present embodiment, after forming the periodic pattern 16, a thin layer of tetraethoxysilane (TEOS) solution was uniformly coated by spincoating onto the FOP 12. Thereafter, the FOP 12 was heated for one hour in a drying oven to a temperature of 160° C., to promote hydrolysis and condensation polymerization reactions by TEOS and thereby formed a silicon dioxide polymer. The silicon dioxide obtained by the above-described reaction formed an extremely dense amorphous film. By the above processing, the optical element portion of the imaging unit 11 was completed.

### A Second Configuration of Optical Element and Imaging Unit

FIG. 5 shows another example of the imaging unit provided with an optical element. The imaging unit 11b shown in FIG. 5 has a configuration such that the wavelength selective film 14 on the incident face functions as a mirror that bends the optical path of the ultraviolet light through 90°. In the description of the imaging unit 11b shown in FIG. 5, the same reference numerals are used to denote the same configuration as the embodiment above, and description will not be repeated.

The FOP 12a of the imaging unit 11b shown in FIG. 5 is ground and polished such that an incident end face (inclined face in FIG. 5) is inclined by 45° with respect to the exit end face (lower face in FIG. 5). The wavelength selective film 14 and the fluorescent film 15 are stacked in ascending order as shown in FIG. 5 on the incident face of the FOP 12a. An image sensing device 13 is mounted on the exit surface of the FOP 12a. It is required that the wavelength selective film 14 in the example shown in FIG. 5 has a configuration used with incidence angle of 45° due to the incident angle of ultraviolet light on the film face.

Since the incidence of short-wavelength ultraviolet light on the FOP 12a is almost completely cut-off by the wavelength selective film 14 in the configuration of the imaging unit 11b shown in FIG. 5, deterioration of the FOP 12a due to the short-wavelength ultraviolet light can be suppressed. Since the measurement light in ultraviolet region is converted to fluorescent light by the fluorescent film 15 and passes through the wavelength selective film 14, accurate measurement can be performed using fluorescent light with the configuration shown in the present embodiment.

### A First Configuration of an Optical Property Measuring Instrument

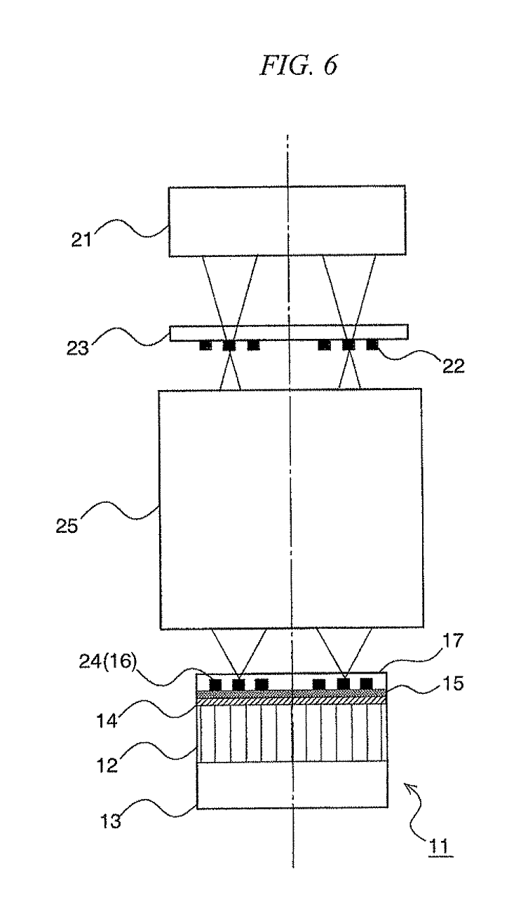

FIG. 6 is a schematic view of an example of an optical property measuring apparatus according to an embodiment of the present invention. The optical property measuring apparatus shown in FIG. 6, for example, is a moire fringe measuring apparatus used in measurement of distortion in a projection optical system of an exposure apparatus. The imaging unit 11 shown in FIG. 1 is incorporated in the optical property measuring apparatus shown in FIG. 6. In the description of configuration of the apparatus in FIG. 6, the same reference numerals are used to denote the same configuration as the embodiment above, and description will not be repeated.

The optical property measuring apparatus shown in FIG. 6 includes an illumination optical system 21 including an ArF excimer laser light source or a KrF excimer laser light source, a substrate 23 provided with the first periodic pattern 22, and the imaging unit 11. In the explanation of FIG. 6, the periodic pattern provided on the imaging unit 11 configures the second periodic pattern 24.

In the optical property measuring apparatus shown in FIG. 6, measurement light from the illumination optical system 21 (short-wavelength ultraviolet light) passes through the first periodic pattern 22 of the substrate 23. The first periodic pattern 22 is arranged on the object plane (or in proximity thereto) of the optical system under examination 25 (the projection optical system of the exposure apparatus), and has a light and dark repeating pattern in a line and space format. The measurement light that is diffracted by the first periodic pattern 22 becomes incident upon the imaging unit 11 through the optical system under examination 25.

The ultraviolet measurement light that is incident upon the imaging unit 11 becomes incident on the fluorescent film 15 by passing through the transmission portion of the second periodic pattern 24. The fluorescent light generated in the fluorescent film 15 by the ultraviolet measurement light passes through the wavelength selective film 14 and is guided to the image sensing device 13 through the FOP 12. In this manner, the image sensing device 13 of the imaging unit 11 detects a moire fringe formed by the measurement light passing through the first periodic pattern 22 and the second periodic pattern 24. Distortion in the optical system under examination 25 is measured based on the detected moire fringe. As described above, since the ultraviolet light passing the fluorescent film 15 is reflected by the wavelength selective film 14, incidence of ultraviolet light on the FOP 12 is almost completely cut-off.

The optical property measuring apparatus shown in FIG. 6 uses the FOP 12 to enable comprehensive and high-accuracy measurement of distortion in a wide range in the image plane of the optical system under examination 25. As a result, a very large relay lens is unnecessary in the optical property measuring apparatus and thereby facilitates downsizing of the apparatus. In the optical property measuring apparatus shown in FIG. 6, since the imaging unit 11 is used in the same configuration as that shown in FIG. 1, deterioration of the FOP 12 due to short-wavelength ultraviolet light is extremely low, and thereby enables maintenance of the durability and reliability of the overall apparatus. Since measurement is enabled using short-wavelength ultraviolet light, measurement accuracy is improved. When the optical system under examination 25 uses short-wavelength ultraviolet light such as an excimer laser or the like, it is possible to measure optical property of the optical system under actual use conditions.

### A Second Configuration of an Optical Property Measuring Apparatus

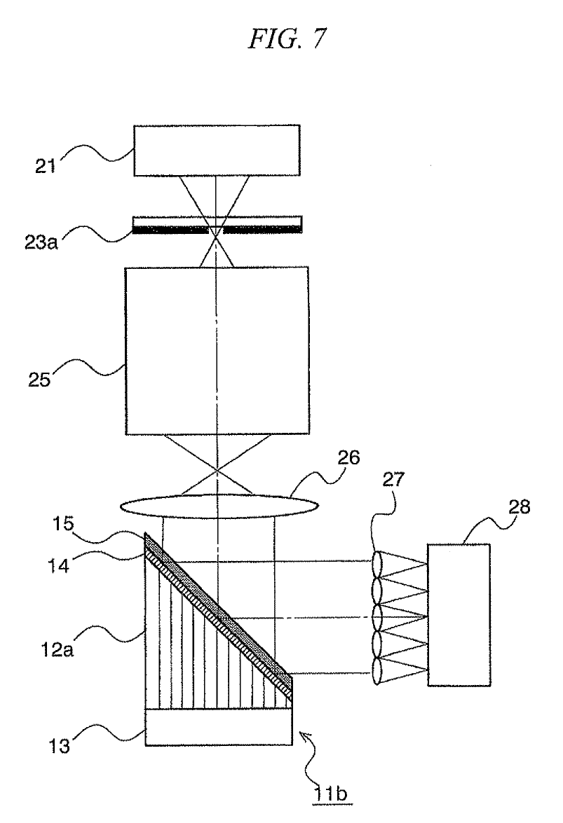

FIG. 7 is a schematic view of another example of an optical property measuring apparatus according to an embodiment of the present invention. The optical property measuring apparatus shown in FIG. 7 may be used in measurement of wavefront aberration and the numerical aperture of the projection optical system of the exposure apparatus. Furthermore the optical property measuring apparatus shown in FIG. 7 incorporates the imaging unit 11b shown in FIG. 5. In the explanation of the configuration of the apparatus shown in FIG. 7, the same reference numerals are used to denote the same configuration as the embodiment above, and description will not be repeated.

The optical property measuring apparatus shown in FIG. 7 includes illumination optical system 21, a substrate 23a provided with a pinhole, a relay lens 26, the imaging unit 11b, a microlens array 27, and a detection device 28.

As shown by FIG. 7, ultraviolet measurement light from the illumination optical system 21 passes through the pinhole provided in the substrate 23a. The pinhole is arranged in the object plane (or in proximity thereto) of the optical system under examination 25. The measurement light that is diffracted by the pinhole is converted to parallel rays by passing through the relay lens 26 via the optical system under examination 25. Then the ultraviolet measurement light passing through the relay lens 26 becomes incident upon the imaging unit 11b.

The imaging unit is arranged such that the incident surface of the FOP 12a in the imaging unit 11b inclines at 45 degree with respect to the optical axis of the optical system under examination 25. Ultraviolet measurement light causes emission of fluorescent light when becoming incident upon the fluorescent film 15 of the imaging unit 11b. This fluorescent light passes through the wavelength selective film 14 of the FOP 12a and is guided to the image sensing device 13 via the FOP 12a. In this manner, the image sensing device 13 of the imaging unit 11a detects the intensity distribution of the measurement light. In this case, since the ultraviolet measurement light passing through the optical system under examination 25 is converted to parallel rays to enable detection of the intensity distribution by the image sensing device 13, the numerical aperture of the optical system under examination 25 can be calculated from the detection result in the image sensing device 13.

The optical path of the ultraviolet light that has passed through the fluorescent film 15 is turned through 90° by reflection by the wavelength selective film 14 of the FOP 12a and thereby becomes incident upon the microlens array 27. The microlens array 27 is arranged at an optically conjugate position (or in proximity thereto) with the pupil-plane of the optical system under examination 25. The ultraviolet measurement light collected by the microlens array 27 becomes incident upon the detection apparatus 28. As a result, the point images of the ultraviolet measurement light collected by the microlens array 27 are detected by the detection apparatus 28. Therefore wavefront aberration in the optical system under examination 25 can be measured from an amount of positional deviation in the detected point images.

In the optical property measuring apparatus shown in FIG. 7, it is possible to measure various optical property of the optical system under examination 25 using fluorescent light which has been generated by the fluorescent film 15 and has passed through the wavelength selective film 14, and ultraviolet measurement light that has been reflected by the wavelength selective film 14. Since the imaging unit 11b having the configuration shown in FIG. 5 is used in the optical property measuring apparatus shown in FIG. 7, deterioration of the FOP caused by short-wavelength ultraviolet light is extremely low and the durability and reliability of the overall apparatus can be maintained.

### A Third Configuration of an Optical Property Measuring Apparatus

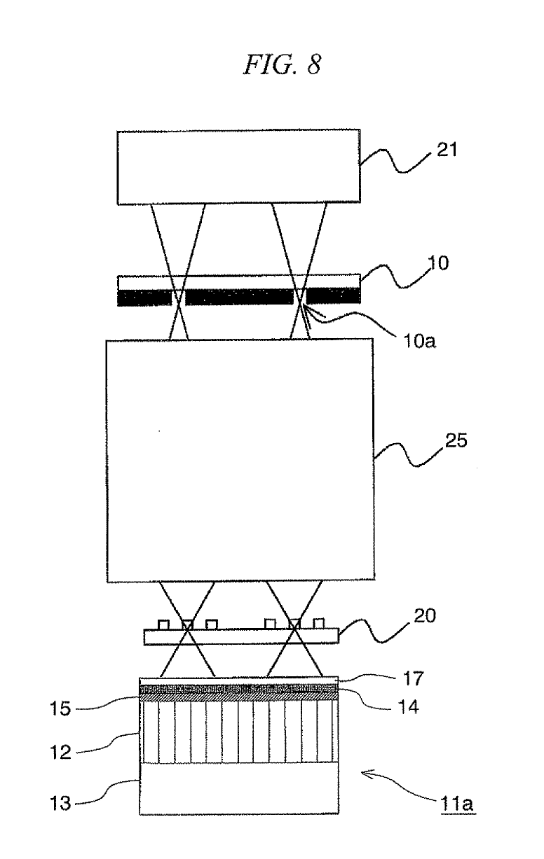

FIG. 8 shows yet another configuration of an optical property measuring apparatus according to the first embodiment, and is a schematic figure of a shearing interferometer. The shearing interferometer shown in FIG. 8 is an apparatus measuring the wavefront aberration (optical property) of the optical system under examination 25, for example, a projection optical system mounted in an exposure apparatus. The imaging unit 11a shown in FIG. 2 is incorporated in the optical property measuring apparatus shown in FIG. 8. As a result, in the description of the apparatus configuration in FIG. 8, the same reference numerals are used to denote the same configuration as the embodiment above, and description will not be repeated.

As shown in FIG. 8, the ultraviolet measurement light from the illumination optical system 21 passes through the pinhole pattern 10a (pattern constituted of a plurality of pinholes) provided in the substrate 10. The ultraviolet measurement light diffracted by the pinhole pattern 10a becomes incident upon a diffraction grating 20 through the optical system under examination 25. The diffraction grating 20 is arranged on the image plane of the optical system under examination 25, or in proximity thereto. The ultraviolet measurement light that has passed through the diffraction grating 20 becomes incident upon the imaging unit 11a.

The ultraviolet measurement light that becomes incident upon the imaging unit 11a is converted to visible measurement light by the fluorescent film 15. The fluorescent film 15 is formed by vapor deposition to have a thickness of less than or equal to the diameter of the individual optical fibers that constitute the FOP 12. The visible measurement light that is converted by the fluorescent film 15 (fluorescent light) passes through the wavelength selective film 14 and is guided to the image sensing device 13 by the FOP 12. The image sensing device 13 detects an interference fringe produced by the interference due to diffracted rays produced by transmission through the diffraction grating 20. Wavefront aberration of the optical system under examination 25 can be measured from the detected interference fringe.

According to the shearing interferometer shown in FIG. 8, a requirement for a large relay optical system or the like is avoided by providing the FOP 12 and thereby enables downsizing of the apparatus. Thus an interference fringe is in a wide region of an image plane of the optical system under examination 25 can be measured with high accuracy in a single operation using a small apparatus.

Since the fluorescent film 15 is formed on the incident surface of the FOP 12 with a thickness that is less than or equal to the diameter of the individual fibers that constitute the FOP 12, ultraviolet measurement light can be converted into visible measurement, and the visible measurement light can be surely guided to the image sensing device 13 while avoiding a reduction in the lateral resolution of the FOP 12. Since the ultraviolet measurement light is converted into visible measurement by the fluorescent film, it is possible to reduce generation of coherent noise. Therefore, there is no requirement to provide a rotating diffusion plate for the purpose of preventing generation of coherent noise and thus the compactness of the apparatus can be further improved.

### Description of a Method of Measuring Optical Property

An example of a method of measuring an optical property of an FOP provided to an optical property measuring apparatus is described below. The FOP itself may include optical properties such as distortion or the like. Therefore, so as to perform accurate measurement using the optical property measuring apparatus, it is desirable to measure the optical properties of the FOP preliminarily.

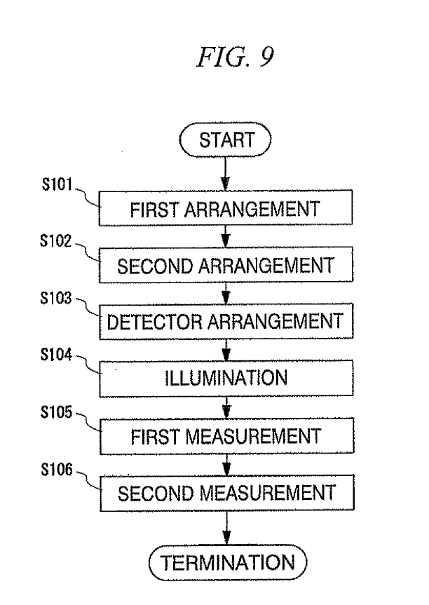

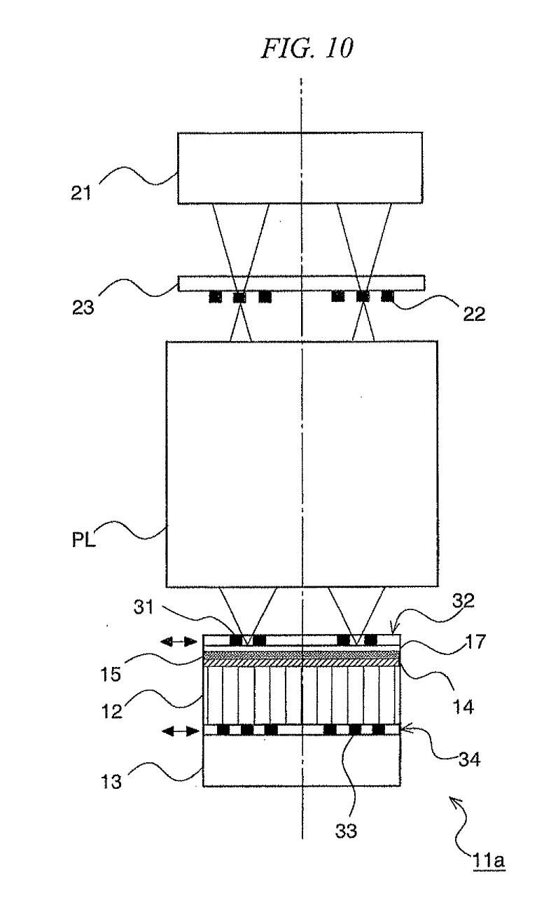

FIG. 9 is a process diagram showing an example of a method of measuring the optical property of the FOP. FIG. 10 is a schematic view of a configuration of an apparatus used in measuring the optical property of the FOP. FIG. 9 and FIG. 10, are explained below for a case of using the imaging unit 11a shown in FIG. 2. In the description in relation to FIG. 9 and FIG. 10, the same reference numerals are used to denote the same configuration as the embodiment above, and description will not be repeated.

Firstly, a first substrate 23 provided with the first periodic pattern 22 is arranged (disposed) on the object plane (or in proximity thereto) of the projection optical system PL, (S101: First arrangement).

Next, the FOP 12 is arranged so that the incident surface of the FOP 12 is positioned on the image plane (or in proximity thereto) of the projection optical system PL, (S102: second arrangement).

In the example shown in FIG. 10, a second substrate 32 on which the second periodic pattern 31 is formed is arranged detachably on the incident surface of the FOP 12. A third substrate 34 on which a third periodic pattern 33 is formed is arranged extractably on the emission surface of the FOP 12. FIG. 10 shows a state where the second substrate 32 is disposed on the incident surface of the FOP 12 and the third substrate 34 is disposed on the emission surface of the FOP 12. The second periodic pattern 31 and the third periodic pattern 33 are respectively periodic patterns, in other words, have a light and dark repeating pattern in a line and space format. The pattern width and the pattern interval of the first periodic pattern 22 and the second periodic pattern 31 may be the same or different. The pattern width and the pattern interval of the first periodic pattern 22 and the third periodic pattern 33 may be the same or different. Preferably, the pattern width and the pattern interval of the second periodic pattern 31 and the third periodic pattern 33 are similar to each other.

Then, the second substrate 32 is disposed on the incident surface of the FOP 12 and the image sensing device 13 is arranged as a detector on the exit surface side of the FOP 12 (S103: Detector arrangement). During the detector arrangement S103, the third substrate 34 may be removed from the emission surface of the FOP 12.

Next, the first periodic pattern 22 is illuminated by the measurement light emitted from the illumination optical system 21 (5104: Illumination).

Next, a first moire fringe formed by the first periodic pattern 22 and the second periodic pattern 31 is measured by the image sensing device 13 (S105: First measurement).

Next, the second substrate 32 is removed from the incident surface side of the FOP 12 and the third substrate 34 is disposed on the exit surface of the FOP 12. Then a second moire fringe formed by the first periodic pattern 22 and the third periodic pattern 33 is measured by the image sensing device 13 (S106: Second measurement).

Where there is no relative positional deviation between the first moire fringe measured in the first measurement S105 and the second moire fringe measured in the second measurement S016, it can be interpreted that there is no distortion in the FOP 12. On the other hand, where there is a relative positional deviation between the first moire fringe and the second moire fringe, it can be interpreted that there is a distortion in the FOP 12. In this case, the distortion amount of the FOP 12 is measured from the amount of relative positional deviation between the first moire fringe and the second moire fringe, and thereby correcting the distortion of the FOP 12 based on the measurement result. Specifically, when optical property of the projection optical system PL are measured, the results of measurement may be calibrated using the measured distortion amount of the FOP 12 as an offset value. Therefore since the distortion in the FOP 12 in the optical property measuring apparatus can be corrected according to the method of measuring optical property, it is possible to measure optical property of the projection optical system PL with high accuracy.

### Description of a Configuration of an Exposure Apparatus

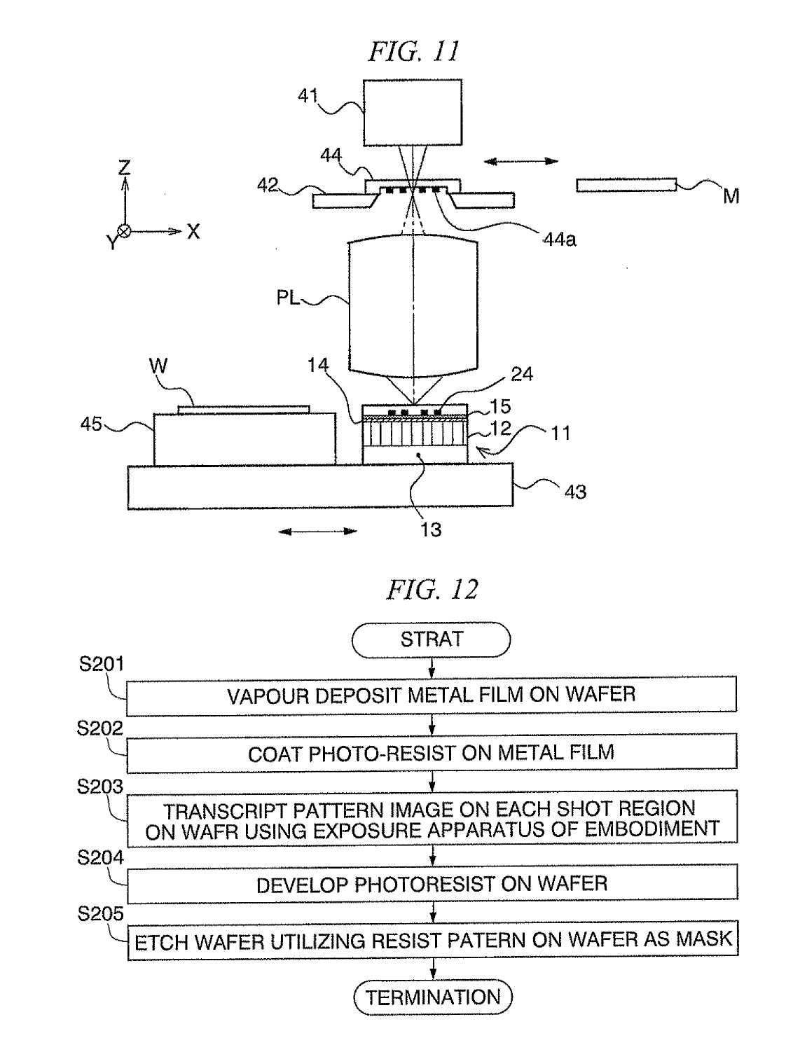

FIG. 11 is a schematic view showing an example of a configuration of an exposure apparatus. With respect to FIG. 11, an example of an exposure apparatus which exposes light onto a wafer (photosensitive substrate) is explained.

In the description hereafter, an XYZ orthogonal coordinate system is set as shown in FIG. 11, and the positional relationship of each member will be described by reference to the XYZ orthogonal coordinate system. The X axis and the Y axis of the XYZ orthogonal coordinate system are parallel to the planer surface of an wafer W, and the Z axis is orthogonal to the planer surface of the wafer W. In FIG. 11, the X axis is parallel to the surface of the page and the Y axis is vertical to the surface of the page.

The exposure apparatus shown in FIG. 11 includes an illumination optical system 41, a mask stage 42, a projection optical system PL, and a wafer stage 43. The illumination optical system 41 includes a light source that supplies exposure light, and the light emitted from the illumination optical system 41 illuminates a mask M at a quantitatively uniform luminance in a superimposing manner. In the example shown in FIG. 11, an Mine lamp, a KrF excimer laser, an ArF excimer laser, a F2 laser and the like may be used as the light source. The above-described light source may also utilize a light source that produces DIN (deep ultraviolet), or VUV (vacuum ultraviolet) light.

The mask stage 42 is arranged on the object plane (or in proximity thereto) of the projection optical system PL. A mask M (or a substrate 44 which has the first periodic pattern 44a and is used in measurement of optical property) is disposed on the mask stage 42.

The projection optical system PL projects a pattern formed on the mask M onto the wafer W. The projection optical system PL is configured by a plurality of optical members and projects the pattern formed on the mask M onto the wafer W at a predetermined magnification (reduction magnification, equal magnification, or an expanding magnification).

The wafer stage 43 has an XY stage that can displace in the directions of the X axis and the Y axis, and a Z stage that can displace in the direction of the Z axis and incline with respect to the Z axis. The wafer stage 43 includes a wafer holder 45 that retains the wafer W by suction. The wafer stage 43 mounts the wafer W on the image plane of the projection optical system PL. According to the above-described configuration, sequential exposure can be performed to transcript a pattern of the mask M to each of exposure regions of the wafer by driving the wafer stage 43 two dimensionally in XY plane.

The exposure apparatus shown in FIG. 11 is provided with the optical property measuring apparatus having the same configuration as shown in FIG. 6 on the wafer stage in order to measure distortion in the projection optical system PL. When the distortion in the projection optical system PL is measured, firstly, the substrate 44 on which the first periodic pattern 44a is formed is mounted onto the mask stage 42. Then the wafer stage 43 is displaced in the X direction to thereby enable illumination of the second periodic pattern 24 that is formed on the incident surface of the FOP 12 using light passing through the projection optical system PL.

Light from the illumination optical system 41 passes through the first periodic pattern 44a and becomes incident upon the imaging unit 11 through the optical system under examination (PL). In the imaging unit 11, ultraviolet light that has passed through the second periodic pattern 24 is converted to fluorescent light by the fluorescent film 15, and that fluorescent light passes through the wavelength selective film 14 and is guided to the image sensing device 13 by the FOP 12. The image sensing device 13 detects the moire fringe formed by the measurement light passing through the first periodic pattern 44a and the second periodic pattern 24. Thus distortion in the projection optical system PL can be measured from the position of the detected moire fringe.

Since the exposure apparatus shown in FIG. 11 is provided with an optical property measuring apparatus (moire fringe measuring apparatus) that enables measurement of distortion in the projection optical system PL, distortion in the projection optical system PL can be measured with a high degree of accuracy. Therefore, the pattern formed on the mask can be transcripted to the wafer by exposure with high accuracy using the projection optical system PL in which the distortion has been corrected based on the results of measurement. The exposure apparatus shown in FIG. 11 may be an immersion exposure apparatus in which a liquid having a refractive index of at least 1 is interposed between the projection optical system PL and the wafer W.

### Description of an Exposure Method and a Method of Manufacturing a Device

In the exposure apparatus shown in FIG. 11, microdevices (including for example, semiconductor devices, image sensing devices, liquid-crystal display devices, thin-film magnetic heads, and the like) may be manufactured through the exposure of the transfer pattern formed by the mask M on the photosensitive substrate (wafer) using the projection optical system PL. The photosensitive substrate may be a substrate (for example, a semiconductor substrate, a glass substrate, a ceramic substrate, a metal substrate) coated with a photosensitive composition (photoresist).

Next, an example of a method of obtaining a semiconductor device (an example of a microdevice) through formation of a circuit pattern on a photosensitive substrate (e.g., wafer) using a scanning exposure apparatus according to the above-described embodiment will be described with reference to the process in FIG. 12.

Firstly, metal film is vapor deposited on one lot of wafer (S201).

Next, a photoresist is coated onto the metal film (onto the metal film on the wafer) on one lot of plate (S202).

To transcript pattern image, a pattern formed on a mask is illuminated by the illumination optical system using the exposure apparatus according to the above-described embodiment (illumination). An image of the illuminated pattern is formed on the wafer with the projection optical system (Image formation). Thus, the pattern is sequentially transcripted (transferred) by exposure to each shot region on the one lot of wafer (S203). The optical property of the projection optical system is measured by the optical property measuring apparatus according to the above-described embodiment, and corrected based on the results of measurement.

Next, the photoresist on the one lot of wafer is developed (S204).

A circuit pattern corresponding to the pattern formed by the mask is formed in each shot region of each wafer by etching using the resist pattern on the one lot of wafer as a mask (S205).

Thereafter, a device such as a semiconductor device is manufactured by further forming a circuit pattern or the like on an upper layer. In the above-described method of manufacturing a semiconductor device, optical property of a projection optical system is measured with high accuracy with the optical property measuring apparatus according to the above-described embodiment, and is corrected based on the results of measurement. As a result, exposure is performed with high accuracy, thereby obtaining a satisfactory semiconductor device.

From the vapor deposition of metal film (S201) to the etching (S205) in FIG. 12, a metal is vapor-deposited on the wafer, a resist is coated onto the metal film, and then exposure, developing and etching are performed. Before these steps, a silicon oxide film may be formed on the wafer, and the resist may be coated on the silicon dioxide film. After that, the exposure, development and etching may be performed.

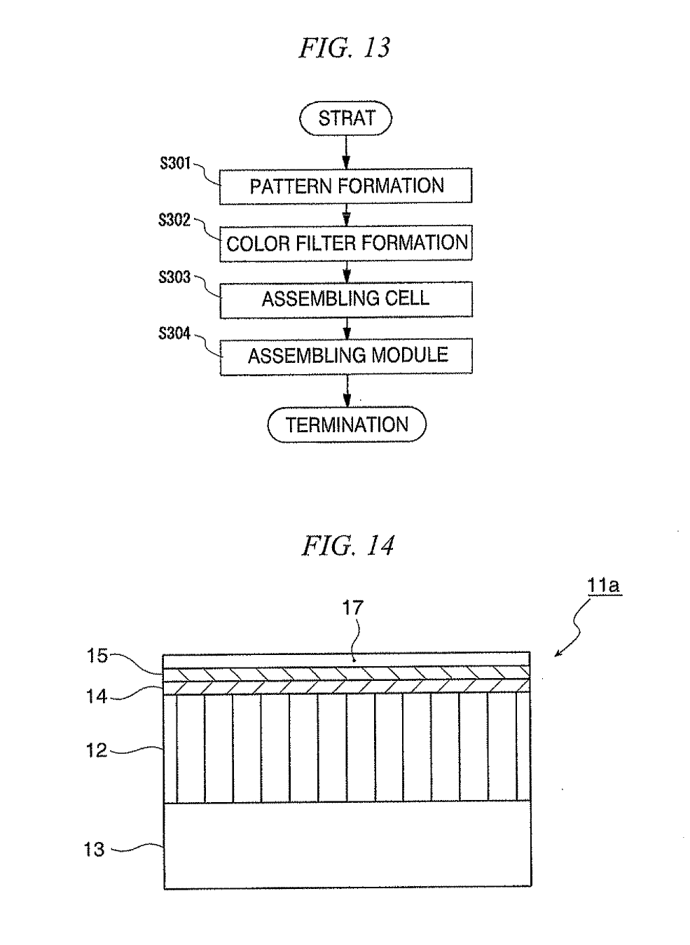

In the exposure apparatus according to the present embodiment, a liquid-crystal display device as an example of a microdevice can be obtained by forming a predetermined pattern (circuit pattern, electrode pattern, or the like) on a plate (glass substrate). An example of the method of forming liquid-crystal display device will be described below making reference to the processing in FIG. 13.

In FIG. 13, in the pattern formation (S301), the pattern of the mask is transferred by exposure to the plate using an exposure apparatus according to the above-described embodiment. This step is so-called photolithography. In the same manner as in the explanation of FIG. 12, the optical property of the projection optical system are measured by the optical property measuring apparatus according to the above-described embodiment, and corrected based on the results of measurement.

In the photolithography, a pattern including a plurality of electrodes or the like is formed on the plate. Thereafter, the exposed plate is subjected to respective steps including development, etching, a resist stripping, and the like, to thereby form a predetermined pattern on the plate. After that, the plate is transferred to the subsequent color filter formation (S302).

In the color filter formation (S302), a color filter is prepared. In the color filter, a plurality of three dot groups corresponding to R (Red), G (Green) and B (Blue) may be arrayed in a matrix configuration in the color filter. Alternatively, a plurality of three stripe filter groups corresponding to R, G, B is arrayed in the direction of the horizontal scanning line in the color filter. After the color filter formation, a cell assembly is performed (S303).

In the cell assembly (S303), a liquid-crystal panel (liquid-crystal cell) is manufactured by injection of liquid crystal between the plate having a pattern obtained in the pattern formation (S301) and the color filter obtained in the color filter formation (S302).

Thereafter in the module assembly (S304), various components including back light or electronic circuits that perform display on the liquid-crystal panel are mounted on the liquid-crystal panel (liquid-crystal cell) assembled in the cell assembly. Thus, manufacture of a liquid-crystal display element is completed.

In the above-described method of manufacturing the liquid-crystal display element, optical property of the projection optical system is measured with high accuracy with the optical property measuring apparatus according to the above-described embodiment, and is corrected based on the results of measurement. Therefore, exposure is performed with high accuracy, thereby obtaining a liquid-crystal display element.

### Supplementary Explanation in Relation to the First Embodiment

(1) In the imaging unit shown in FIG. 1 and FIG. 2, the presence of a protective film on the surface of the fluorescent film is not always necessary. In each of the imaging units in the above-described embodiments, an additional thin film (for example, a protective film of a fluoride) may be provided between the FOP and wavelength selective film, or between the wavelength selective film and the fluorescent film.
(2) The optical element as shown in each of the above embodiments (FOP forming a fluorescent film and a wavelength selective film) or the imaging unit having such an optical element may be widely applied to an optical property measuring apparatus using ultraviolet light. For example, the above optical element may be applied to an interferometer or a transmittance measurement apparatus, or the like.

### Second Embodiment

FIG. 14 shows an imaging unit according to a second embodiment of the present invention.

The imaging unit 11a is provided with a FOP 12 configured as a bundle of a plurality of optical fibers, an image sensing device 13 disposed on an exit surface of the FOP 12, and a wavelength selective film 14, a fluorescent film 15, and a protective film 17 stacked on the incident surface of the FOP 12. Except for the fact that the periodic pattern 16 is not provided, the configuration of the imaging unit 11a is substantially similar to that of the imaging unit 11 according to the first embodiment of the present invention.

In the imaging unit 11a, the wavelength selective film 14 is constituted as a film that transmits fluorescent light and reflects ultraviolet light. A plurality of types of dielectric thin layers each formed with an optical thickness of λ/4 of the designed central wavelength are stacked in the wavelength selective film 14. A multilayer dielectric film is constituted of the wavelength selective film 14 and the fluorescent film 15. The wavelength selective film 14 is disposed between the FOP 12 and the fluorescent film 15 to thereby configure an optical element. The optical element is arranged on the light receiving surface of the image sensing device 13 formed of a visible light CCD, and the exit surface of the FOP 12 is adhered or made contact to the light receiving surface of the image sensing device 13 to thereby configure the imaging unit 11a.

In this imaging unit 11a, when ultraviolet light is irradiated (illuminated) to the incident surface side of the FOP 12, the light passes through the protective film 17, reaches the fluorescent film 15, and at least a part of the ultraviolet light is converted to visible light by exciting the fluorescent film 15 to emit florescent light. Ultraviolet light that passes through the fluorescent film 15 without becoming visible reaches the wavelength selective film 14 and is reflected. On the other hand, the fluorescent light passes the wavelength selective film 14, reaches the incident surface of the FOP 12, and is guided by the FOP 12 to reach the light receiving surface of the image sensing device 13 and imaged.

The-above described imaging unit 11a enables observation or measurement of ultraviolet light with a visible-light CCD. For example, by using a fluorescent film 15 formed by doping an activator such as a transition metal or a rare earth metal in a base material made of a fluoride and a wavelength selective film 14 made of a fluoride, it is possible to observe or measure ultraviolet light having a wavelength of 193 nm by a visible-light CCD.

During the observation and measurement of ultraviolet light, the FOP 12 does not tend to be deteriorated by the ultraviolet light since the ultraviolet light is reflected by the wavelength selective film 14. Even when a part of the ultraviolet light reaches the FOP 12, the ultraviolet light does not reach the image sensing device 13 since the FOP 12 does not transmit ultraviolet light. Therefore, the visible-light CCD is not damaged by ultraviolet light.

Since the fluorescent film 15 is a thin film formed by doping an activator in a base material, the fluorescent film 15 may be easily disposed on the incident surface of the FOP 12 without requiring substantial space for arrangement.

In addition, it is possible to facilitate observation or measurement of ultraviolet light with high accuracy while preventing unsharpening of the ultraviolet light and fluorescent light during transmission in the fluorescent film 15.

Since a function of reflecting ultraviolet light and emitting fluorescent light is achieved by merely providing a multilayer dielectric film constituted of the fluorescent film 15 and the wavelength selective film 14 on the FOP 12, it is possible to simplify the configuration. In particular, in the present embodiment, since the fluorescent film 15 is provided separately to the multilayer dielectric film constituting the wavelength selective film 14, the fluorescent film 15 can be formed with a higher thickness than the multilayer dielectric film that constitutes the wavelength selective film 14 and thereby increasing the intensity of fluorescent light emitted from the fluorescent film 15.

### Third Embodiment

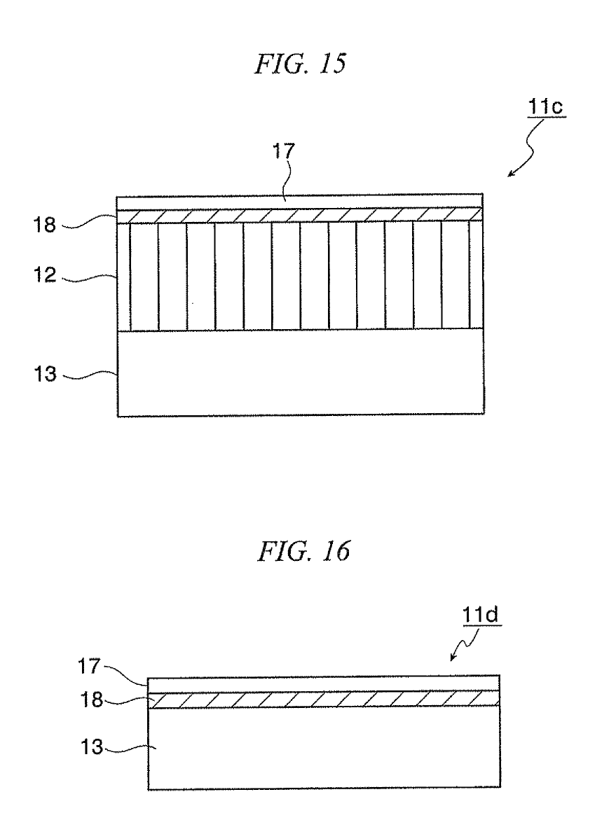

FIG. 15 shows an imaging unit according to a third embodiment of the present invention.

In the imaging unit 11c, the optical element is configured by stacking a fluorescent multilayer dielectric film 18 on the incident surface of the FOP 12 in substitution for the wavelength selective film 14 and the fluorescent film 15 of the second embodiment of the present invention. In other respects, the configuration is the same as that according to the second embodiment of the present invention.

The fluorescent multilayer dielectric film 18 is configured by stacking a plurality of dielectric thin films, where at least one of the dielectric thin films is composed of a fluorescent film formed with a predetermined thickness. The dielectric thin film formed from a fluorescent film may be a single layer, may be a plurality of layers, or may be all of the layers. An increase in the number of layers of fluorescent films increase the intensity of fluorescent light emitted by the fluorescent multilayer dielectric film 18.

The fluorescent multilayer dielectric film 18 may constitute a wavelength selective film that reflects ultraviolet light and transmit fluorescent light. For example, such a wavelength selective film may be formed by stacking 42 layers of dielectric thin films while controlling the optical thickness of all of the dielectric thin films including the fluorescent film to be λ/4 of the designed central wavelength.

In the imaging unit 11c, when ultraviolet light is irradiated onto the incident surface side of the FOP 12, the ultraviolet light passes through the protective film and reaches the fluorescent multilayer dielectric film 18. Although the incident ultraviolet light is reflected by the stacking structure of the multilayer dielectric film 18, a part of the ultraviolet light is converted to visible light since the ultraviolet light is irradiated onto the fluorescent film constituting a layer of the fluorescent multilayer dielectric film 18 and excite the fluorescent film to emit fluorescent light. This fluorescent light is transmitted through the fluorescent multilayer dielectric film 18, reaches the incident surface of the FOP 12, and is guided by the FOP 12 to reach the light receiving surface of the image sensing device 13 and is imaged.

The same operation effect as second embodiment of the present invention may be obtained by using the above-described imaging unit 11c. For example, measurement or observation of ultraviolet light with a visible-light CCD may be performed, and damage to the image sensing device 13 or deterioration of the FOP 12 due to ultraviolet light are prevented using the imaging unit 11c. The film shape of the fluorescent material facilitates arrangement on the incident surface of the FOP 12 and prevents blurring of the ultraviolet light or the fluorescent light during transmission. Since a function of reflecting ultraviolet light and a function of emitting fluorescent light are enabled by the fluorescent multilayer dielectric film 18, it is possible to simplify the configuration. In the present embodiment, a function of emitting fluorescent light is obtained by merely configuring the fluorescent multilayer dielectric film 18 having a property of reflecting ultraviolet light. Therefore, it is possible to simplify the configuration of an optical element.

The second and third embodiments may be suitably varied within the scope of the invention. For example, although observation and measurement of ultraviolet light was described above with reference to an image sensing device 13, another method such as visual observation or the like may be used without the providing an image sensing device 13 to enable observation and measurement of the ultraviolet light.

Although an example using a FOP 12 as an optical base member was described above, another optical base member can be used.

The above-described embodiments are explained for the case where the FOP 12 is disposed on the light receiving surface of the image sensing device 13, and the fluorescent film 15 or fluorescent multilayer dielectric film 18 is disposed on the incident surface side of the FOP 12. The embodiments are not limited to such an case. For example, an imaging unit may be constituted by providing the fluorescent film 15 or fluorescent multilayer dielectric film 18 on the light receiving surface of the image sensing device 13 without using an optical base such as a FOP 12 or the like.

As shown in FIG. 16, the fluorescent multilayer dielectric film 18 and the protective layer 17 may be stacked on the light receiving surface of the image sensing device 13, and the fluorescent multilayer dielectric film 18 may be placed in contact with the light receiving surface of the image sensing device 13. This type of configuration also enables reflection of ultraviolet light by the fluorescent multilayer dielectric film 18, and enables fluorescent light emitted by the fluorescent film of the fluorescent multilayer dielectric film 18 to be received by the light receiving surface of the image sensing device 13 and imaged by the image sensing device 13.

### Fourth Embodiment

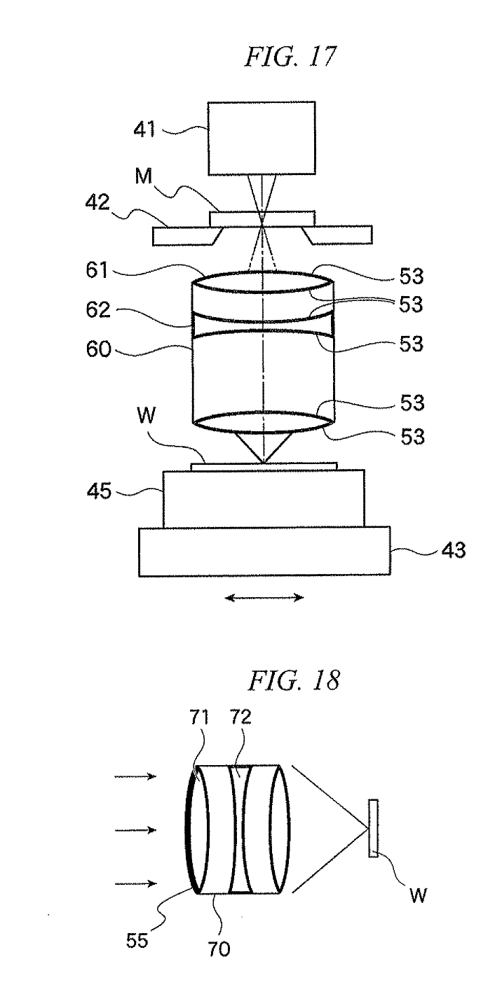

FIG. 17 is a schematic view of an exposure apparatus provided with an optical element according to the fourth embodiment of the present invention. Constitution of the exposure apparatus is similar to the exposure apparatus described with reference to the first embodiment except for the constitution of the projection optical system 60.

The projection optical system 60 is configured by arraying a plurality of optical elements 61, 62, . . . (a plurality of optical elements including optical elements 61, 62) such as a lens or the like. Ultraviolet light from the illumination optical system 41 is illuminated through the mask stage 42. The ultraviolet light is converged to a preferred light flux in the projection optical system 60, and then illuminates the wafer W. A predetermined optical path is formed in the projection optical system 60. In the fourth embodiment of the present invention, an antireflection film 53 constituted of the multilayer dielectric film is provided on at least one, and preferably both, of the incident surface and exit surface of the at least one or plurality of optical elements 61, 62 . . . that configure the illumination optical system 41.

Each optical element 61, 62 . . . is configured by stacking the antireflection film 53 on a surface of an optical base member that transmits ultraviolet light emitted from the illumination optical system 41 and transmits visible light. For example, the optical base member may be formed from silica glass, a calcium fluoride crystal or the like.

The antireflection film 53 is formed by stacking a plurality of dielectric thin films, where at least one layer of the dielectric thin films is a fluorescent film. Here, high refractive-index layers and low refractive-index layers are stacked alternately, where the high refractive-index layer has a refractive index higher than that of the optical base member, and the low refractive-index layer has a refractive index lower than that of optical base member. The high refractive-index layer and the low refractive-index layer are both formed of fluorides. The fluorescent film may be either a high refractive-index layer or a low refractive-index layer, and may form one layer, a plurality of layers, or all of the layers of the antireflection film 53. An increase in the number of layers of fluorescent films will increase the intensity of fluorescent light emitted by the optical element 61, 62 . . . .

In an exposure apparatus provided with the above-described optical elements 61, 62 . . . , when ultraviolet light from the illumination optical system 41 is illuminated through the mask stage 42 to the projection optical system 60, reflection is prevented by the antireflection film 53 of each of the optical elements 61, 62 . . . , and transmission of ultraviolet light at a high transmittance is enabled. Furthermore ultraviolet light is made visible by emission of fluorescent light by the fluorescent film in the antireflection film 53 of each of the optical elements 61, 62 . . . to thereby enable observation and measurement of the optical path of the ultraviolet light in the projection optical system 60.

As a result, observation and measurement of ultraviolet light in the projection optical system 60 may be performed easily without using a device such as beam checker or the like to visualize ultraviolet light. Since each of the antireflection film 53 has high durability, it is possible to arrange the optical elements 61, 62, . . . normally in the exposure apparatus and observe and measure the ultraviolet light constantly. Since the fluorescent film of the antireflection film 53 is sufficiently thin, the optical path of the projection optical system 60 is not changed by the presence of the antireflection films. Therefore, it is possible to design the optical path of the projection optical system 60 easily.

Although a fluorescent film was provided in the optical element 61, 62 . . . constituting the projection optical system 60 in the above-explained embodiment, the embodiment of the present invention may be applied to different optical system constituted of different optical elements.

In the above-explained embodiment, optical elements and an optical system were capable of transmitting ultraviolet light. Alternatively, as shown in FIG. 18, an optical system 70 may be configured by optical elements 71, 72, . . . (a plurality of optical elements containing 71, 72) made of one or more optical base member that transmit visible light and do not transmit ultraviolet light, and a fluorescent film 55 having a sufficient thickness may be provided on the incident surface of the optical element 71 irradiated with ultraviolet light such that visible light emitted by the fluorescent film 55 passes through each of the optical elements 71, 72, . . . and forms an optical path.

Embodiments of the present invention may be executed in other various configurations without departing from its spirit and scope. While embodiments of the invention have been described and illustrated above, it should be understood that these are exemplary of the invention and are not to be considered as limiting. The invention is not to be considered as being limited by the foregoing description, and is only limited by the scope of the appended claims. Furthermore modifications and variations within a scope that is equivalent to the scope of the claims are all within the scope of the present invention.

### EXAMPLES

Examples according to some embodiments of the present invention will be described below.

### Fluorescent Material

A fluorescent material used as a raw material in vapor deposition was prepared by synthesizing a fluorescent material containing an activator in a fluoride base material and sintering the fluorescent material to a sintered body.

As shown in Table 1, the base material was selected from lanthanum fluoride (LaF₃), calcium fluoride (CaF₂), yttrium fluoride (YF₃), CLF, a solid-solution mixed crystal of calcium fluoride and yttrium fluoride (CYF: CaₓY₁₋ₓF₃₋ₓ), and gadolinium fluoride (GdF₃). The activator was selected from one or two of europium (Eu), terbium (Tb), praseodymium (Pr), samarium (Sm), dysprosium (Dy), cerium (Ce), holmium (Ho), erbium (Er), or ytterbium (Yb). Each of the fluorescent materials was synthesized using the concentrations of the activator shown in Table 1. The color of the fluorescent light obtained when ultraviolet light is illuminated on each sintered body was shown in Table 1. The concentration in Table 1 shows the concentration of the activator relative to the cationic component of the base material by atomic %.

Raw material powder used in the synthesis of each fluorescent material was prepared by a method, for example, described in Japanese Unexamined Patent Application, First Publication No. 2006-206359. Microcrystal particles of CLF, LaF₃, CaF₂, YF₃, CYF, or GdF₃ produced by the above-described hydrothermal synthesis were mixed with an aqueous acetate solution of a rare earth metal (Eu, Tb, Pr, Sm, Dy, Ce, Ho, Er, or Yb), thereby obtaining each raw material powder.

The raw material powder was press-molded into a pellet shape, and each pellet was subjected to high-temperature sintering using an electrical furnace at a temperature of 800° C. for one hour. It is considered that the rare earth metal ions diffuse into the microcrystals of base-material, undergo substitution at cationic sites, and/or intrude interstitial spaces in the lattice structure during sintering to thereby become activated.

TABLE 1

| Base | | Activator | | Film |
|---|---|---|---|---|
| Material | Activator | Concentration | Fluorescent Color | Formed |
| CLF | Tb | 6% | Green | O |
| | Eu | 1% | Red/Orange | O |
| | Er | 1% | Blue Green | — |
| | Pr | 3% | Violet | — |
| | Yb | 3% | Blue | — |
| | Gd | 3% | Red Violet | — |
| | Nd | 3% | Blue Violet | — |
| | Ho | 3% | Blue Violet | — |
| | Sm | 1% | Orange | O |
| | Dy | 1% | Yellowish White | O |
| | Tb, Yb | 3% | Green | — |
| CaF₂ | Eu | 8% | Orange - Red | — |
| | Tb | 8% | Green | O |
| | Eu | 1% | Blue Violet | — |
| LaF₃ | Tb | 1%-6% | Green | O |
| | Pr | 1% | Blue Violet | O |
| | Ce | 0.01-1% | Blue Violet | — |
| | Eu | 1% | Orange - Red | O |
| | Sm | 1% | Orange | O |
| | Dy | 1% | Yellowish White | — |
| YF₃ | Tb | 1% | Green | O |
| | Pr | 1% | Blue Violet | — |
| CYF | Tb | 1% | Blue Green | — |
| | Pr | 1% | Blue Green | — |
| GdF₃ | Tb | 5% | Green | O |
| | Pr | 5% | Red/Orange | O |

### Fluorescent Film

A light having a wavelength of 193 nm was irradiated to the thus formed fluorescent materials. Fluorescent materials that showed strong fluorescence (materials indicated by open circles ◯ in the “film formed” column in Table 1) were used in formation of fluorescent films. As shown in Table 1, where the fluorescent material was prepared by selecting the base material from the group including lanthanum fluoride (LaF₃), yttrium fluoride (YF₃), gadolinium fluoride (GdF₃), and calcium lanthanum fluoride (CLF), and the activator was selected from the group including europium (Eu), terbium (Tb), and praseodymium (Pr), strong fluorescent light emission was confirmed when the light having of 193 nm in wavelength was radiated to the fluorescent materials.

The fluorescent film was formed by disposing each fluorescent-material sintered body on a Mo boat and depositing a fluorescent film onto a substrate using a resistance heating type vacuum vapor deposition apparatus. The substrate was parallel plate-type silica glass (φ30) and the film thickness was 500 nm. During vacuum vapor deposition, the substrate was heated to 300° C. to improve the strength and film properties of the fluoride film, and to increase the efficiency of fluorescent light emission by improving the crystallinity through growing the fluoride crystal particles in the film and promoting dispersion of the activator.

### Measurement

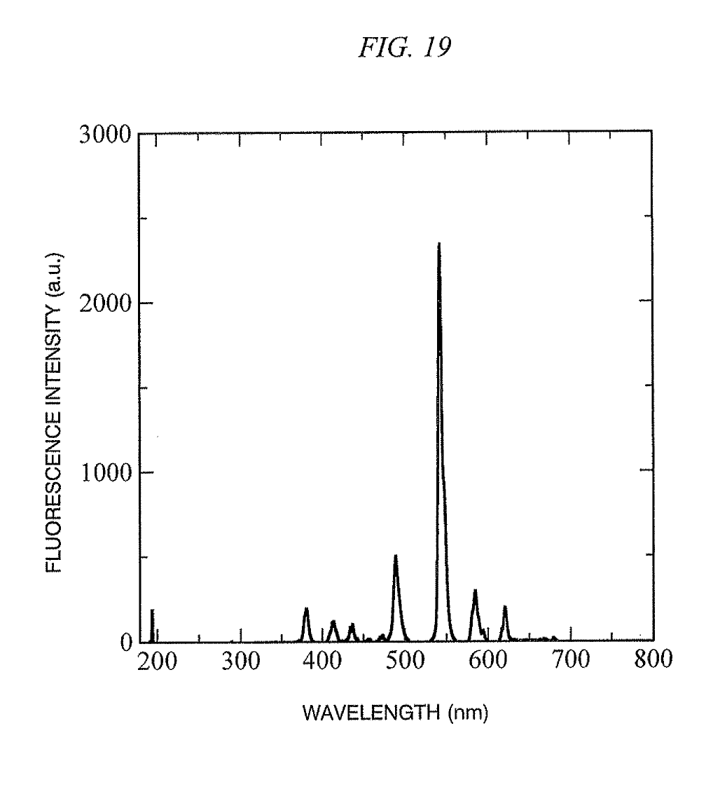

A preferable combination of base material and activator for the fluorescent film was investigated by illumination of laser light having a wavelength of 193 nm onto the prepared fluorescent film and measurement of the fluorescent spectrum using an optical fiber spectrometer. A representative example of the fluorescent spectrum with respect to a LaF₃:Tb fluorescent film is shown in FIG. 19.

Firstly, the fluorescent peak intensity of a fluorescent film was compared for the cases of forming fluorescent films using a base material of LaF₃ and an activator selected from different rare earth metals (Eu, Sm, Pr, and Tb). Table 2 shows the respective intensity and the respective fluorescent light peak wavelength, where the respective fluorescent peak intensity was normalized by the fluorescent peak intensity of LaF₃:Eu which was assigned to be 1.

These results show that the fluorescent light emitted by a LaF₃:Tb fluorescent film is remarkably stronger, particular in the visible region, than fluorescent light emitted from the film including other activators. An intensity of the fluorescent light emitted by LaF₃:Tb fluorescent film was 270 times greater than the fluorescent peak intensity of a LaF₃:Eu film using the same base material and an Eu activator under the same conditions.

In view of these results, when the fluorescent intensity was compared with respect to a fluorescent film prepared by limiting the activator to Tb and using a different fluoride in the base material, the results as shown in Table 3 were obtained.

As a result, LaF₃:Tb, the combination of a LaF₃ base material and Tb activator was determined to be optimal with respect to ultraviolet light having a wavelength of 193 nm.

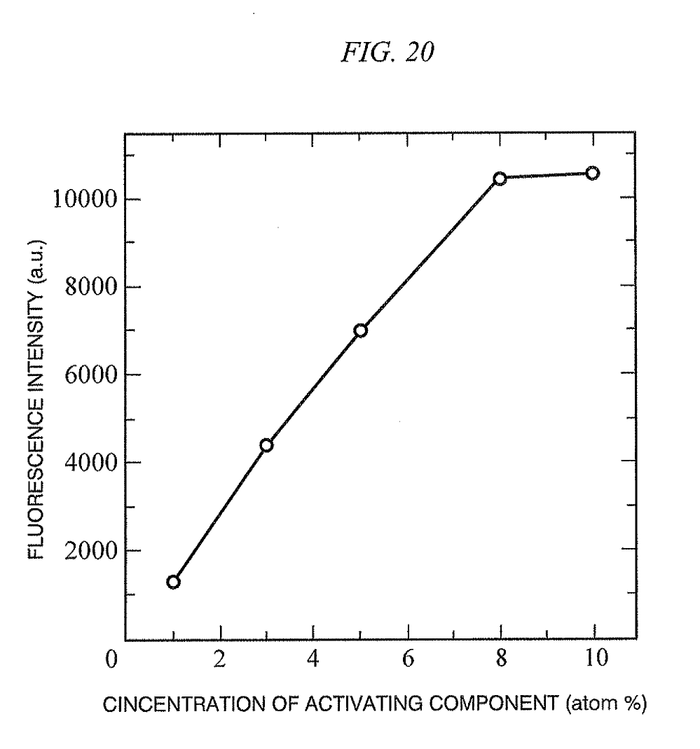

As shown in FIG. 20, the fluorescent intensity of a fluorescent film increases in a substantially proportional manner within a Tb activator concentration of 1 to 8 atom %.

TABLE 2

| | Activator | Fluorescent | (Relative value | |
|---|---|---|---|---|
| | (Concentration | Peak | assigning a | Peak |
| Base | was 1% in | Intensity | value of 1 | Wavelength |
| Material | all case) | (Arbitrary unit) | to LaF₃:Eu) | nm |
| LaF₃ | Eu | 8.469 | 1 | 613 |
| | Sm | 1.4265 | 0.164 | 600 |
| | Pr | 883.3 | 102 | 395 |
| | Tb | 2341.3 | 270 | 543 |

TABLE 3

| | Activator | Fluorescent | (Relative value |
|---|---|---|---|
| | (Concentration | Peak | assigning a |
| Base | was 1% in | Intensity | value of 1 |
| Material | all case) | (Arbitrary unit) | to LaF₃:Tb) |
| CaF₂ | Tb | 249.3 | 0.106 |
| YF₃ | | 1268.8 | 0.541 |
| CLF | | 1362.2 | 0.581 |
| LaF₃ | | 2341.3 | 1 |
| GdF₃ | | 1177.7 | 0.503 |

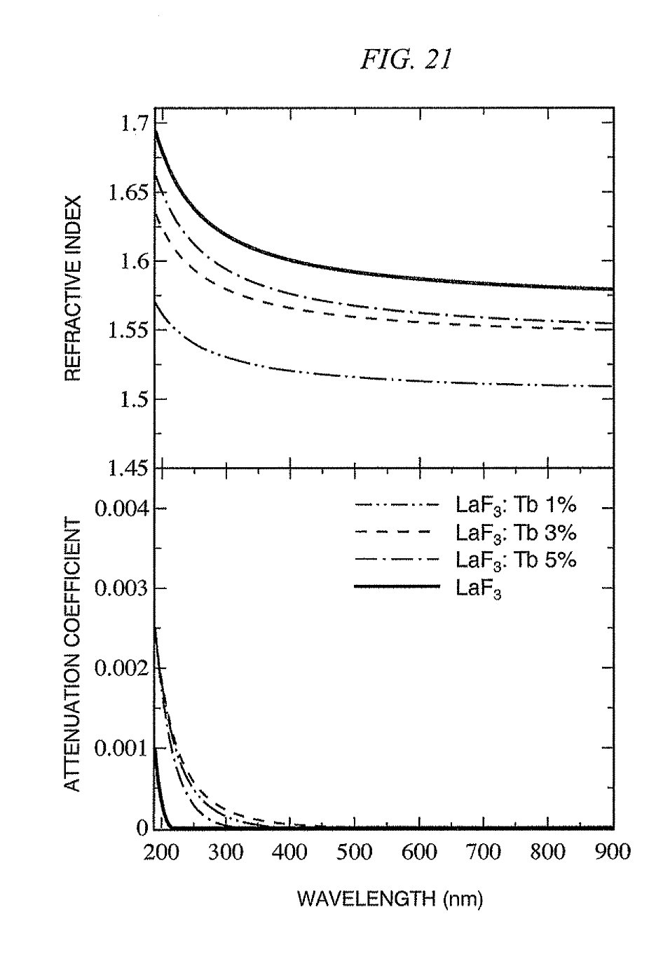

Then the spectral transmittance of the fluorescent film was measured, FIG. 21 shows the variance of the optical constants (refractive index n and extinction coefficient k) calculated using the reflectance and the spectral transmittance of a LaF₃:Tb (concentration of activator was 1, 3, and 5 atom %) fluorescent film. The refractive index and extinction coefficient were calculated based on a Forouhi-Bloomer model.

When the LaF₃:Tb fluorescent film in the present embodiment had a 1-atom % activator concentration, the refractive index was lower than that of generally used LaF₃ film. The extinction coefficient was about 2.24×10⁻³ at 193 nm which was larger than that of LaF₃ film used for a vacuum ultraviolet.

Since a part of the vacuum ultraviolet light must be absorbed to emit fluorescent light, a certain level of loss is unavoidable. However, the absorption is not likely to result in film damage due to heat, since the absorbed energy is dissipated as light in the fluoride fluorescent material. Such loss includes the scattering effect resulting from remarkable growth of LaF₃ columnar structures resulting from the formation of a film which is thick for a 500 nm optical thin film. This scattering effect is suppressed by decreasing the thickness of the film (for example, using an optical film thickness of approximately 30 nm which corresponds to λ/4). In this case, sufficient fluorescent light intensity can be obtained by increasing the total film thickness of the fluorescent film in a multilayer structure.

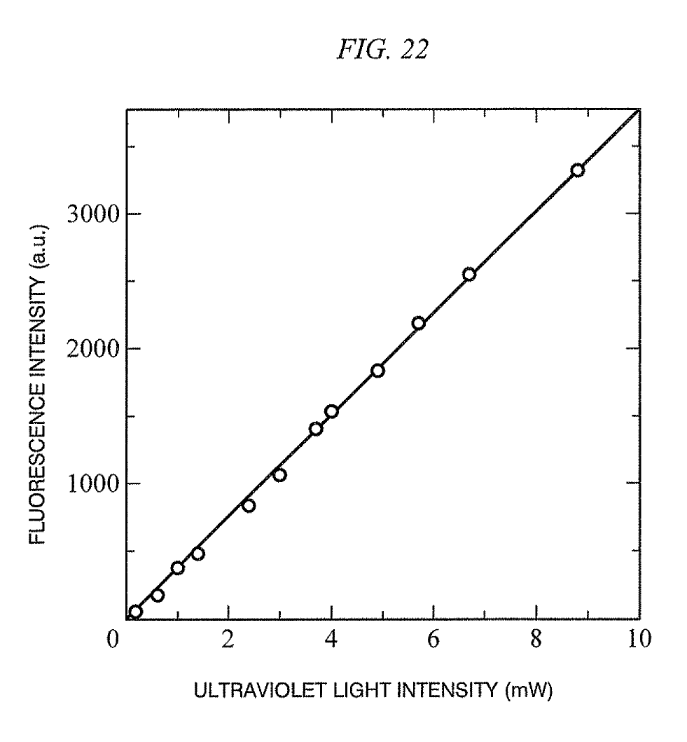

FIG. 22 shows the relationship between fluorescent intensity in the case of irradiating ultraviolet light having a wavelength of 193 nm onto the fluorescent film and the radiant flux of ultraviolet light. These results show that the fluorescent intensity increases proportional to the intensity of the ultraviolet light. This fact means that the fluorescent intensity distribution reflects distribution of the ultraviolet light intensity, thereby enabling estimation of the distribution of the ultraviolet light intensity.

It was confirmed that a combination of LaF₃:Tb was suitable for a fluorescent film excited by light having a wavelength of 193 inn. This combination is extremely useful in an optical system utilizing 193 mm laser light, since the fluorescent film may substitute a LaF₃ film that is generally used as a high refraction index film in an optical system that utilizes 193 nm laser light.

From the results shown in Table 1 and Table 2, it was confirmed that combinations of a LaF₃ base material and a Pr activator or combination of any of YF₃, CLF, GdF₃ as a base material and Tb as an activator had a relatively high utility since relatively high fluorescent peak intensity was observed in those combinations. It is considered that other combinations as shown in the film column in Table 1 can be used to obtain a fluorescent film with respect to short-wavelength ultraviolet light (for example, light with a wavelength of 193 nm) by adjustment of activator concentration or film deposition conditions.

### Examples of Application of Fluorescent Film

The below described explanation is related to an application of an fluorescent film as an optical thin film to impart fluorescence (fluorescent light emission) function to a normal antireflection film or a multilayer dielectric highly-reflective mirror. The LaF₃ layer used as the optical thin film was controlled to have a thin thickness at most a half-wavelength of the designed central wavelength, in other words, approximately 100 nm. Where a fluorescent film of this thickness is used as an optical thin film, the fluorescent intensity must be as high as possible. The combination of LaF₃:Tb identified in a embodiment of the present invention has been confirmed to emit sufficiently strong fluorescent light. The fluorescent film may be used as a single film that has a fluorescence function.

### Antireflective Fluorescent Film

An antireflection film was constituted using the combination of LaF₃ and Tb (LaF₃:Tb) that was preferred as a fluorescent film for light having a wavelength of 193 nm.

The basic antireflection film had a designed central wavelength λₒ of 193 nm, and was constituted of a base material made of quartz glass (refractive index: 1.55), and total of six layers including LaF₃ layers acting as high-refractive index layers (refractive index: 1.69), and MgF₂ layers acting as low-refractive index layers (refractive index: 1.42). The respective optical film thickness from the base material side was set to be 0.26λₒ for the first layer, 0.08λₒ for the second layer, 0.10λₒ for the third layer, 0.33λ for the fourth layer, 028λₒ for the fifth layer, and 027λₒ for the sixth layer. The first, third and fifth layer of these layers were LaF₃ layers and the other layers were MgF₂ layers. The reason for selecting the above-described constitution was so that the total thickness of the LaF₃ layers had a high value of approximately 100 nm, and thereby increasing the intensity of the fluorescent light emission when the LaF₃ layers were substituted by fluorescent films.

When the LaF₃ layers in the basic antireflection film were substituted by LaF₃:Tb (5 atom % activator) fluorescent film layers, an antireflective fluorescent film was constituted. Therefore, an antireflective fluorescent film was formed without further modification to the constitution.

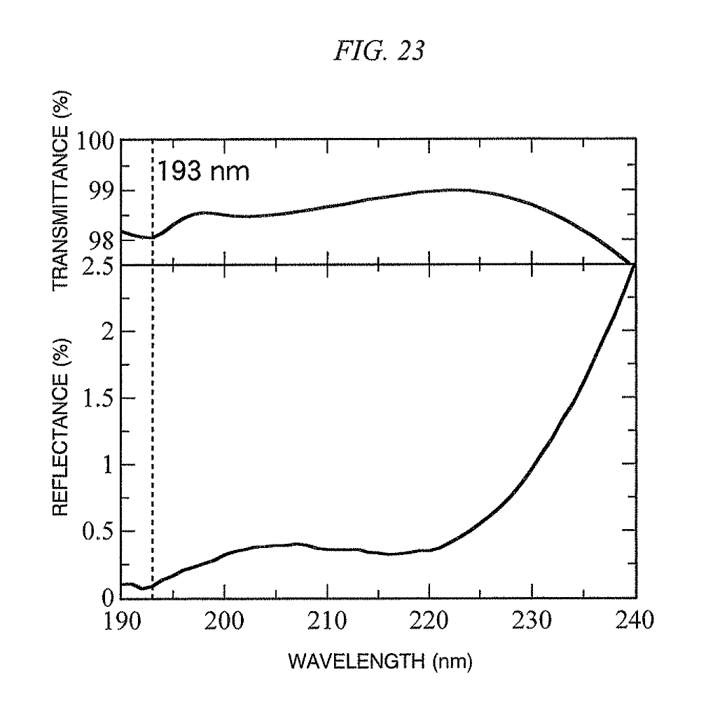

Next, the above described antireflective fluorescent film was deposited onto both surfaces of a parallel plate-type quartz glass to thereby measure spectral reflectance and transmittance. The results are shown in FIG. 23. Reflectance decreased to a level of 0.1% in proximity to a wavelength of 193 nm and thereby an antireflection effect was sufficiently obtained. The wavelength at which the reflectance undergoes the highest decrease was 192 nm which was shifted toward short wavelengths than 193 nm. This phenomenon is due to slightly lower refractive index and slightly larger loss in a LaF₃:Tb fluorescent film in comparison to a LaF₃ thin film.

On the other hand, the transmittance was approximately 98% at 193 nm. Although the transmittance was lower than that of the basic antireflection film, this transmittance is not so low compared to a transmittance of substantially 90% of a bare silica glass which does not have a film on both sides thereof. Where the loss resulting from emission of fluorescent light is taken into consideration, it can be interpreted that a high transmittance has been maintained.

Next, two silica glass lenses having an antireflective fluorescent film deposited thereon were prepared. One lens was a concave lens with a focal distance of f=−150 mm, and the other lens was a convex lens with a focal distance of f=300 mm. The antireflective fluorescent film was deposited on both surfaces of the respective lenses.

An optical system was configured by arranging the concave lens in upstream side in the optical path of laser light having a wavelength of 193 nm, and arranging the convex lens at a distance of 150 mm in downstream side. The optical system configures the most simple beam expander.

Green fluorescent light was emitted from both the incident surface and the exit surface of each lens. Light and dark pattern reflecting the intensity distribution in the cross-section of the laser beam was clearly visible in the fluorescent emission image. In addition, it was confirmed that the beam cross-section expanded from the concave lens towards the convex lens to have approximately twice the diameter.

### Multilayer Dielectric Film Mirror

A multilayer dielectric film mirror was configured using the combination of LaF₃ and Tb that was preferred as a fluorescent film with respect to light having a wavelength of 193

The basic multilayer dielectric film mirror was a reflective mirror for reflecting 193 nm light, wherein the base material was fluorite, and lanthanum fluoride (LaF₃) and magnesium fluoride (MgF₂) were alternately stacked by multilayer vapor deposition. The multilayer film was constituted of 42 layers where lanthanum-fluoride layers and magnesium-fluoride layers each having an optical film thickness of ¼ of the designed central wavelength of 193 nm were stacked alternately from the base material side. It was confirmed that the multilayer dielectric film had a high reflectance of at least 99% for the light of 193 nm in wavelength band. The reason for selecting the above-described configuration for the multilayer dielectric film mirror was that the total thickness of the LaF₃ layers had a thick value of approximately 500 nm resulting in high fluorescence intensity where the LaF₃ layers were substituted by the fluorescent films.

Where the LaF₃ layers in the basic multilayer dielectric film mirror are substituted by LaF₃:Tb (5 atom % activator) fluorescent film layers, a fluorescent light multilayer dielectric film mirror is configured without further modification.

The fluorescent light multilayer dielectric film mirror is not only a highly-reflective mirror with respect to ultraviolet light vertically incident upon the film surface, but can also be used as a multilayer dielectric film mirror designed with respect to a 45° incidence to bent the optical path by 90°, or for other incident angles.

### Imaging Unit

The imaging unit 11a shown in FIG. 14 according to the second embodiment of the present invention and the imaging unit 11c shown in FIG. 15 according to the third embodiment of the present invention were configured.

Optical fibers manufactured by the SCHOTT AG having a diameter of 6 μm were used in the FOP 12. Both end faces of the FOP 12 were subjected to optical-polishing and washed preliminarily before film deposition.

Next, the multilayer dielectric film mirror was formed as a wavelength selective film 14 on the incident surface side of the FOP 12. The designed central wavelength was set to 193 nm. Lanthanum fluoride (LaF₃) and magnesium fluoride (MgF₂) were alternately stacked by multilayer vapor deposition. 42 layer of lanthanum fluoride layers and magnesium fluoride layers were stacked alternately from the FOP 12 side, where each layer had an optical film thickness of λ/4 of the designed central wavelength. This wavelength selective film 14 had a high reflectance of at least 99% for the light of 193 nm wavelength band and reflected almost all ultraviolet light.

Next, the fluorescent film 15 was formed by vacuum vapor deposition of a fluorescent material onto the surface of the multilayer dielectric film mirror. The fluorescent film 15 was deposited by vacuum vapor deposition using the composition of LaF₃:Tb (concentration of activator was 5 atom %) that was preferred as a fluorescent film with respect to light having a wavelength of 193 nm.

The exit surface of the FOP 12 was adhered or made contact to the light receiving surface of the imaging unit 13, thereby constituting the imaging unit 11 shown in FIG. 15.

Next, the multilayer dielectric film mirror in the above described example was deposited onto the incident surface of the FOP 12 to thereby configure the imaging unit 11 in FIG. 15 in the same manner. In this case, the fluorescent light was emitted by several layers from the top of the multilayer dielectric film mirror. Since the fluorescent light emission region and the FOP 12 are in closer proximity, a fluorescent light image of converted ultraviolet light becomes incident at a high resolution upon the incident surface of the FOP 12 and thereby increases the resolution of the fluorescent light image transferred to the exit surface.

Where a fluorescent light image emitted from the FOP 12 is imaged by the imaging unit 11 of the above-described configurations, it is possible to visualize an image formed by ultraviolet light of 193 nm in wavelength and take the image by a visible-light CCD. The FOP 12 and the image sensing device are inferior in photo-durability for ultraviolet light of 193 nm in wavelength and reliability of their performance may be deteriorated by direct exposure to the ultraviolet light. However, deterioration of the FOP 12 due to the ultraviolet light can be suppressed by using the combination of the fluorescent film 15 and the wavelength selective film 14 and/or the multilayer dielectric film mirror. In addition, it is possible to suppress the cost by using a visible-light CCD as the image sensing device 13.

The fluorescent film according to some embodiments of the present invention can be formed with a thickness substantially similar to a normal optical film on an optical substrate, and therefore has a high degree of freedom in its arrangement. In contrast to conventional sintered powder, scattering of visible light or ultraviolet light due to pores do not occur in the fluorescent film. Therefore, it is possible to measure ultraviolet light incident upon the fluorescent film with high accuracy by detecting the fluorescent light. The multilayer dielectric film according to an embodiment of the present invention enables a combination of the function as an antireflection film, a wavelength selective film, or the like with a function as a fluorescent film. Application of a function as an antireflection film enables prevention of ultraviolet-light damage to an optical base member while guiding visible light generated in the fluorescent film to the optical base member. By using the optical element provided with the fluorescent film or the multilayer dielectric film in an optical property measuring apparatus, it is possible to measure the optical property of various optical systems with high accuracy by using short-wavelength ultraviolet light. In this manner, the accuracy of an optical apparatus such as an exposure apparatus can be improved, and manufacture of a high-accuracy device using such an apparatus can be enabled.

1. A fluorescent film comprising
a base material constituted of a fluoride that can transmit ultraviolet light, and an activator doped in the base material, wherein the activator contains a transition element or a rare earth element and emits fluorescent light in the base material by irradiation of the ultraviolet light.

2. The fluorescent film according to claim 1, wherein the ultraviolet light includes vacuum ultraviolet light.

3. The fluorescent film according to claim 2, wherein the vacuum ultraviolet light includes light of 193 nm in wavelength.

4. The fluorescent film according to claim 1, wherein the base material is selected from one of a group, or a mixture or compound of two or more of the group consisting of neodymium fluoride (NdF₃), lanthanum fluoride (LaF₃), gadolinium fluoride (GdF₃), dysprosium fluoride (DyF₃), lead fluoride (PbF₂), hafnium fluoride (HfF₂), magnesium fluoride (MgF₂), yttrium fluoride (YF₃), aluminum fluoride (AlF₃), sodium fluoride (NaF), lithium fluoride (LiF), calcium fluoride (CaF₂), barium fluoride (BaF₂), strontium fluoride (SrF₂), cryolite (Na₃AlF₆), and chiolite (Na₅Al₃F₁₄).

5. The fluorescent film according to claim 4, wherein the base material is selected from one of a group consisting of lanthanum fluoride (LaF₃), yttrium fluoride (YF₃), gadolinium fluoride (GdF₃), and calcium lanthanum fluoride (CaₓLa₁₋ₓF₃₋ₓ, where x is larger than 0 and smaller than 1).

6. The fluorescent film according to claim 5, wherein the activator is selected from one or more of a group consisting of europium (Eu), terbium (Tb), and praseodymium (Pr).

7. The fluorescent film according to claim 1, wherein the concentration of the activator relative to the cationic component of the base material is greater than or equal to 1% and less than or equal to 10% in an atomic percent concentration.

8. The fluorescent film according to claim 1, wherein the base material is constituted of lanthanum fluoride (LaF₃), the activator is constituted of terbium (Tb), and the concentration of terbium (Tb) relative to lanthanum (La) is greater than or equal to 8% and less than or equal to 10% in an atomic percent concentration.

9. An optical property measuring apparatus that is configured to measure optical property of an optical system under examination, the instrument comprising:
an imaging unit including the fluorescent film according to claim 1; a light guide member that comprises a bundle of a plurality of optical fibers; and an image sensing device arranged to enable imaging of fluorescent light from the fluorescent film,
wherein the imaging unit is arranged on an image plane side of the optical system, and detects measurement light passing through the optical system.

10. The optical property measuring apparatus according to claim 9, comprising: a first periodic pattern arranged on an object plane of the optical system under examination; and a second periodic pattern arranged on an incident surface or exit surface of the light guide member,
wherein the image sensing device detects a moire fringe formed by the first periodic pattern and the second periodic pattern.

11. The optical property measuring apparatus according to claim 9, further comprising a pinhole, a relay lens, a micro lens array, and a detector, wherein
the pinhole is arranged on the object plane of the optical system under examination;
the imaging unit includes a wavelength selective film between the light guide member and the fluorescent film and is arranged such that an incident surface of the light guide member is inclined by 45 degrees from an optical axis of the optical system under examination;
the relay lens is arranged between the image plane of the optical system and the incident surface of the imaging unit;
the detector is arranged such that an incident surface of the detector is perpendicular to the image plane of the optical system;
the micro lens array is arranged between the incident surface of the imaging unit and the detector;
the relay lens converts a measurement light diffracted by the pinhole into parallel light;
the wavelength selective film of the imaging unit transmits fluorescent light generated in the fluorescent film and forms reflected light by reflecting the measurement light passing through the fluorescent film in an direction orthogonal to the incident direction;
the image sensing device of the imaging unit detects fluorescent light guided by the light guide member, and
the detector detects the reflected light condensed by the micro lens array.

12. The optical property measuring apparatus according to claim 9, comprising
a pinhole arranged on an object plane of the optical system under examination; and
a diffraction grating arranged on the image plane of the optical system; wherein the imaging unit detects an interference fringe formed by the diffraction grating.

13. An exposure apparatus that is configured to forming a pattern arranged on a first surface on a photosensitive substrate arranged on a second surface, comprising the optical property measuring apparatus according to claim 9.

14. An exposure method to forming an image of a pattern arranged on a first surface on a photosensitive substrate arranged on a second surface, the method comprising:
performing illumination of the pattern; and
forming an image of the pattern illuminated by the illumination onto the photosensitive substrate using an optical system measured by the optical property measuring apparatus according to claim 9.

15. A method of manufacturing a device, comprising:
performing exposure of an image of a pattern onto a photosensitive substrate using the exposure method according to claim 14; and
developing the photosensitive substrate exposed by the exposure.

16. An imaging unit comprising the fluorescent film according to claim 1, and an image sensing device that is arranged such that an image of fluorescent light from the fluorescent film can be taken using a light receiving surface of the image sensing device.

17. The imaging unit according to claim 16, further comprising a light guide member configured as a bundle of a plurality of optical fibers, and one or a plurality of dielectric thin films positioned between the fluorescent film and the light guide member, wherein the dielectric thin film configures the wavelength selective film that has a function of transmitting the fluorescent light and reflecting the ultraviolet light.

18. The imaging unit according to claim 16, wherein the outer side of the fluorescent film is covered by a protective film having at least one of a water-resistant property and a water-repellant property.

19. A multilayer dielectric film comprising at least one fluorescent film according to claim 1.

20. The multilayer dielectric film according to claim 19, wherein the multilayer dielectric film is the wavelength selective film that has a function of transmitting the fluorescent film and reflecting the ultraviolet light.

21. The multilayer dielectric film according to claim 19, wherein the multilayer dielectric film is an antireflection film that prevents reflection of the ultraviolet light.

22. An optical element wherein the fluorescent film according to claim 1 arranged on a surface of an optical base member.

23. An optical element wherein the multilayer dielectric film according to claim 19 is arranged on a surface of an optical base member.

24. An optical system comprising an array of a plurality of optical elements, wherein at least one or all of the plurality of optical elements are constituted by an optical element that has the multilayer dielectric film according to claim 21 on a surface thereof.
